(19) United States
(12) Patent Application Publication
(10) Pub. No.: US 2011/0306212 A1
(43) Pub. Date: Dec. 15, 2011

(54) SUBSTRATE PROCESSING APPARATUS, SEMICONDUCTOR DEVICE MANUFACTURING METHOD AND SUBSTRATE MANUFACTURING METHOD

(75) Inventors: Akihiro SATO, Toyama (JP); Akinori TANAKA, Toyama (JP); Takeshi ITOH, Toyama (JP); Masanao FUKUDA, Toyama (JP); Kazuhiro MORIMITSU, Toyama (JP)

(73) Assignee: HITACHI KOKUSAI ELECTRIC INC., Tokyo (JP)

(21) Appl. No.: 13/158,089

(22) Filed: Jun. 10, 2011

(30) Foreign Application Priority Data
Jun. 10, 2010 (JP) 2010-132606

(51) Int. Cl. H01L 21/306; B05C 19/00; C23F 1/00; C23F 1/08

(52) U.S. Cl. 438/706; 156/345.33; 156/345.24; 216/63; 257/E21.219

(57) ABSTRACT

Embodiments described herein relate to a substrate processing apparatus includes a reaction tube, a processing chamber provided inside the reaction tube to process a substrate therein, an induction target provided inside the reaction tube to surround the processing chamber and configured to heat the substrate, a heat insulator provided inside the reaction tube to surround the induction target, an induction target provided outside the reaction tube to inductively heat at least the induction target, a first gas supply unit for supplying a first gas into the processing chamber, and a second gas supply unit for supplying a second gas to a first gap provided between the induction target and the heat insulator.

### CROSS-REFERENCE TO RELATED APPLICATIONS

This application is based upon and claims the benefit of priority from Japanese Patent Application No. 2010-132606, filed on Jun. 10, 2010, the entire contents of which are incorporated herein by reference.

### TECHNICAL FIELD

The present disclosure relates to a substrate processing apparatus, a semiconductor device manufacturing method and a substrate manufacturing method.

### BACKGROUND

A substrate processing apparatus for depositing silicon carbide (SiC) or other substances is designed to heat a plurality of substrates horizontally arranged on a susceptor at a temperature of 1500 to 1800° C. and to supply a source gas for deposition into a reaction chamber from a single source.

Japanese Patent Laid-Open Publication No. 2006-196807A discloses a vacuum deposition apparatus and a thin film formation method, in which the substrate-holding surface of a susceptor is arranged to face downward in an effort to solve problems such as the adhesion of deposits caused by source gas supplied to an opposite surface opposite the susceptor, and the instability of epitaxial growth caused by the generation of source gas convection.

Further, Japanese Patent Laid-Open Publication No. 2005-209668A (see FIG. 5) discloses a substrate processing apparatus provided with a heater unit 20, in which a nitrogen gas 31 is introduced into a gap 5 between an inner tube 2 and an outer tube 3 to prevent adhesion of byproducts to the outer circumferential surface of the inner tube 2.

Similarly to Japanese Patent Laid-Open Publication No. 2005-209668A, Japanese Patent Laid-Open Publication No. 2002-164298A discloses a technique of supplying a gas into a gap between the members constituting a heater unit. More specifically (see FIG. 1 of Japanese Patent Laid-Open Publication No. 2002-164298A), a heater 16 having a cylindrical heat insulator 23 and a heating wire 11 arranged on the inner circumferential surface of the heat insulator 23 is provided between a heater case 21 having a reaction tube therein and a soaking tube 17. A nitrogen gas for facilitating a cooling action is introduced into a third cylindrical space 22, i.e., a gap between the heater case 21 and the cylindrical heat insulator 23. The nitrogen gas is then allowed to flow into the cylindrical heat insulator 23 through a gas outlet 25 formed at an upper portion of the heater.

If substrates are required to be heated at a high temperature of, e.g., 1500 to 1800° C. (specifically at 1600° C. as disclosed in Japanese Patent Laid-Open Publication No. 2006-196807A), an induction heating method may be employed, where an heat-induction target arranged within a reaction tube is inductively heated by an inductor provided outside the reaction tube. The inventors of the present disclosure noted that, in the substrate processing apparatus required to perform heating at a high temperature as discussed above, a heat insulator (or adiabatic material) needs to be arranged between the reaction tube and the induction target in order to prevent degradation of the reaction tube. However, it is also noted that if the heat insulator is arranged between the reaction tube and the induction target, the gas supplied into a processing chamber may be in contact with the heat insulator, which causes damage to the heat insulator, thereby generating particles. Thus, the generated particles may adhere to substrates, which may possibly reduce the substrate processing yield rate and the substrate processing productivity.

Japanese Patent Laid-Open Publication No. 2005-209668A neither discloses arranging the heat insulator between the reaction tube and the induction target nor takes into consideration the possible degradation of the heat insulator as explained above. The cylindrical heat insulator 23 disclosed in Japanese Patent Laid-Open Publication No. 2002-164298A is arranged outside the reaction tube to which a reaction gas is supplied. Thus, similar to Japanese Patent Laid-Open Publication No. 2005-209668A, Japanese Patent Laid-Open Publication No. 2002-164298A fails to recognize the issues related to degradation of the cylindrical heat insulator 23 caused by the reaction gas.

### SUMMARY

According to one aspect of the present disclosure, there is provided a substrate processing apparatus, including: a reaction tube; a processing chamber provided inside the reaction tube configured to process a substrate therein; an induction target provided inside the reaction tube to surround the processing chamber and configured to heat the substrate; a heat insulator provided inside the reaction tube to surround the induction target; an inductor provided outside the reaction tube and configured to inductively heat at least the induction target; a first gas supply unit configured to supply a first gas into the processing chamber; and a second gas supply unit configured to supply a second gas into a first gap formed between the induction target and the heat insulator.

According to another aspect of the present disclosure, there is provided a semiconductor device manufacturing method, including: inductively heating an induction target with an inductor, the induction target being provided inside a reaction tube and surrounding a processing chamber, the inductor being provided outside the reaction tube; insulating energy generated from the induction target from the reaction tube with a heat insulator surrounding the induction target; supplying a first gas from a first gas supply unit into the processing chamber; and supplying a second gas from a second gas supply unit to a first gap formed between the induction target and the heat insulator.

According to still another aspect of the present disclosure, there is provided a substrate manufacturing method, including: maintaining an atmosphere inside a processing chamber at a predetermined temperature by inductively heating an induction target with an inductor, the induction target being provided inside a reaction tube to surround the processing chamber, the inductor being provided outside the reaction tube, with a heat insulator provided inside the reaction tube to surround the induction target and configured to insulate energy generated from the induction target from reaction tube; and processing a substrate arranged within the processing chamber by supplying a first gas from a first gas supply unit into the processing chamber and supplying a second gas from a second gas supply unit to a first gap formed between the induction target and the heat insulator.

### BRIEF DESCRIPTION OF THE DRAWINGS

FIG. 1 is a perspective view showing a substrate processing apparatus according to a first embodiment.

FIG. 2 is a side section view showing a processing furnace according to the first embodiment.

FIG. 3 illustrates a configuration of a gas supply system of the processing furnace according to the first embodiment.

FIG. 4 is a top section view of the processing furnace according to the first embodiment.

FIG. 5 is an explanatory view showing the pressure difference between the respective gaps formed in the processing furnace according to the first embodiment.

FIG. 6 is a schematic view showing a configuration of the processing furnace and a periphery thereof in the substrate processing apparatus according the first embodiment.

FIG. 7 is a block diagram illustrating a configuration of controlling respective units of the substrate processing apparatus according the first embodiment.

FIG. 8 is a section view showing flow holes of a heat insulator provided in a processing furnace according to a second embodiment.

FIG. 9A is a section view showing one example of a labyrinth structure of the flow holes shown in FIG. 8, and FIG. 9B is a section view showing another example of the labyrinth structure.

FIG. 10 is side section view showing a processing furnace according to a third embodiment.

FIG. 11 illustrates a configuration of a gas supply system of the processing furnace according to the third embodiment.

FIG. 12 is a top section view showing the processing furnace according to the third embodiment.

FIG. 13 is a gas supply timing chart explaining a semiconductor device manufacturing method according to the third embodiment.

### DETAILED DESCRIPTION

### First Embodiment

A first embodiment of the present disclosure will now be described in detail.

### (1) Configuration of Substrate Processing Apparatus

First, the configuration of a substrate processing apparatus 10 according to a first embodiment will be described with reference to the accompanying drawings.

<Overall Configuration>

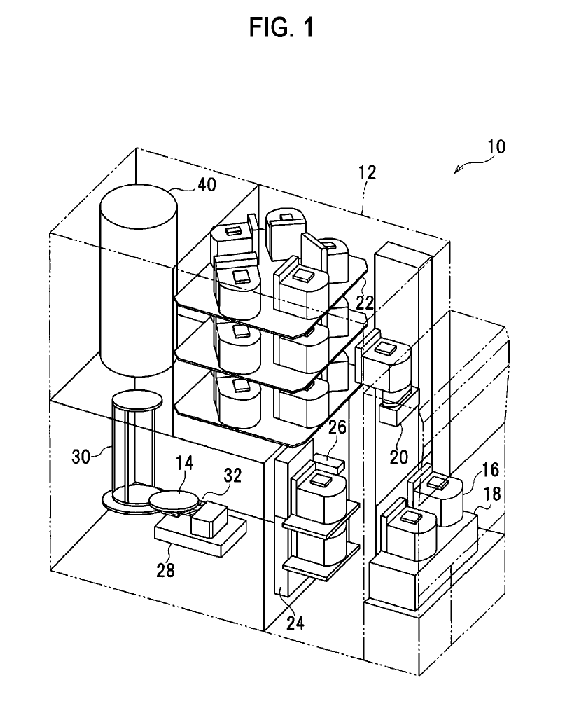

FIG. 1 is a perspective view showing a substrate processing apparatus 10 according to a first embodiment. As shown in FIG. 1, the substrate processing apparatus 10 is a batch-type vertical heat treatment apparatus. The substrate processing apparatus 10 includes a housing 12 in which main units such as a processing furnace 40 are provided. A pod 16 is provided as a substrate conveying container (or wafer carrier) for conveying substrates into the housing 12. For example, twenty five wafers 14 (as substrates) made of silicon (Si) or silicon carbide (SiC) are held within the pod 16. A pod stage 18 is arranged at the front side of the housing 12. The pod 16 is placed on the pod stage 18 with its lid kept in a closed state.

A pod conveying device 20 is provided at the front side (the right side in FIG. 1) inside the housing 12 in an opposing relationship with the pod stage 18. In the vicinity of the pod conveying device 20, there are provided a pod rack 22, a pod opener 24 and a wafer number detector 26. The pod rack 22 is arranged above the pod opener 24 and is configured to hold a plurality of pods 16 placed thereon. The wafer number detector 26 is provided near the pod opener 24. The pod conveying device 20 is configured to convey the pod 16 between the pod stage 18, the pod rack 22 and the pod opener 24. The pod opener 24 is configured to open the lid of the pod 16. The wafer number detector 26 is configured to detect the number of the wafers 14 held within the pod 16 while the lid thereof is opened.

A wafer transfer machine 28 and a boat 30 (used as a substrate support member) are provided within the housing 12. The wafer transfer machine 28 includes an arm (or tweezer) 32 and can be vertically and rotationally moved by a drive unit (not shown in the drawings). The arm 32 is designed to take out, e.g., five wafers 14 at one time out of the boat or the pod. By moving the arm 32, the wafers 14 are conveyed between the boat 30 and the pod 16 positioned on the pod stage 18.

The boat 30 may be made of a heat-resistant material, such as carbon graphite or silicon carbide (SiC), which can endure at a temperature of, e.g., 1550° C. to 1800° C. The boat 30 is configured to hold a plurality of wafers 14 in a vertically stacked and concentrically aligned state.

The processing furnace 40 is installed at the rear upper side within the housing 12. The boat 30 charged with a plurality of wafers 14 is loaded into the processing furnace 40 from the bottom end side thereof.

<Configuration of Processing Furnace>

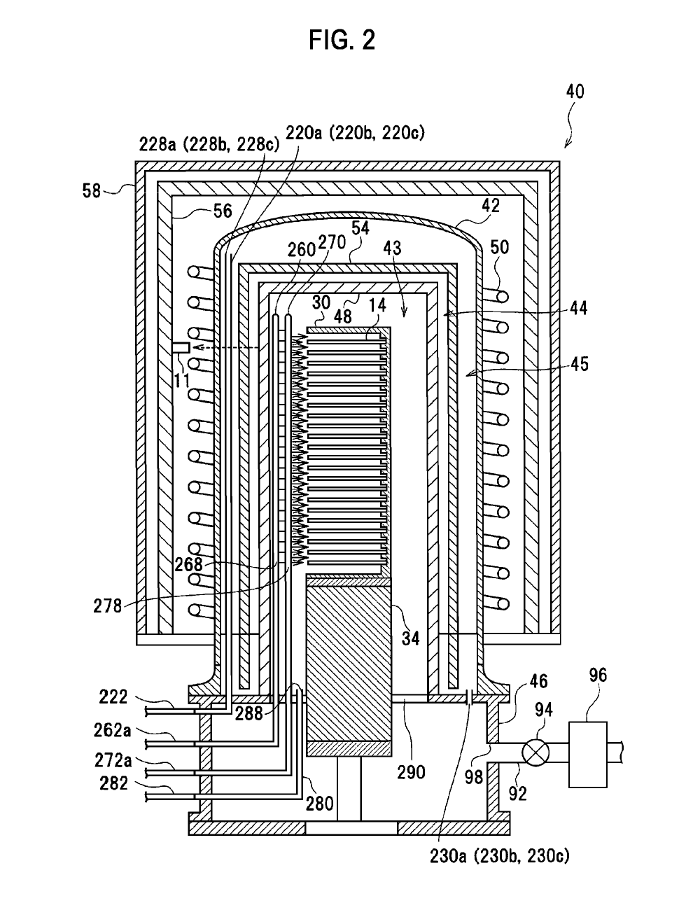

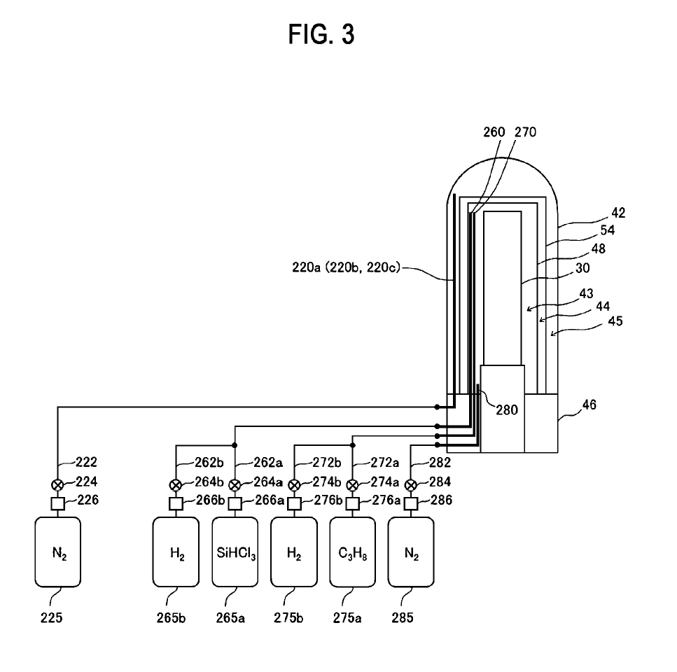

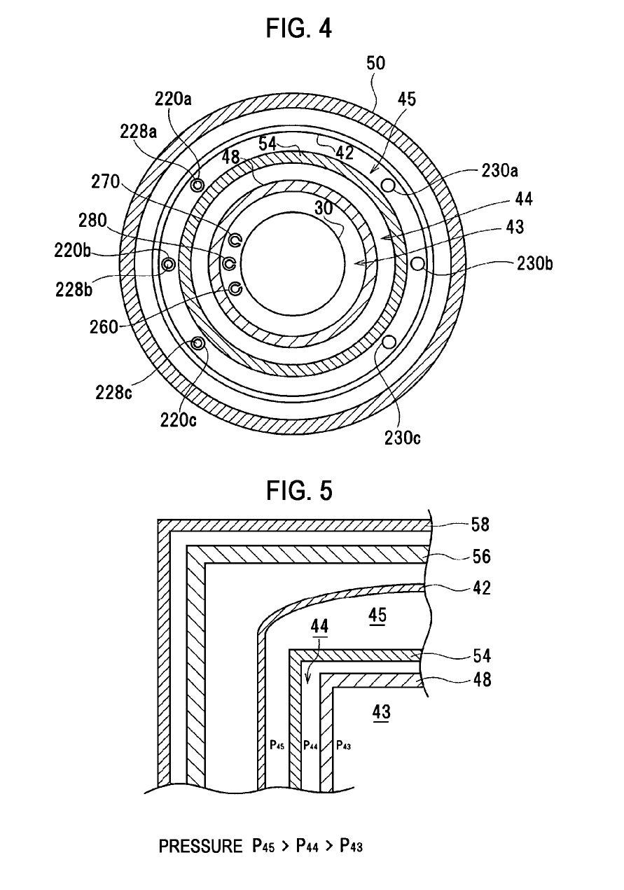

Next, the processing furnace 40 according to the first embodiment will be described with reference to FIGS. 2 through 4. FIG. 2 is a side section view showing the processing furnace 40 according to the present embodiment. FIG. 3 illustrates a configuration of a gas supply system of the processing furnace 40 according to the present embodiment. FIG. 4 is a top section view of the processing furnace 40 according to the present embodiment.

(Reaction Vessel)

As shown in FIG. 2, the processing furnace 40 includes a reaction tube 42, e.g., made of a heat-resistant material such as quartz (SiO₂) or silicon carbide (SiC). The reaction tube 42 is formed in a cylindrical shape with a sealed top end and an open bottom end. A processing chamber 43 surrounded by an induction target 48 (which will be described below) is defined by the tubular hollow space inside the reaction tube 42. The processing chamber 43 is configured to accommodate the wafers 14 as substrates made of, e.g., Si or SiC, which are held by the boat 30 in a vertically stacked and concentrically aligned state. Arranged below the boat 30 is a boat heat-insulating portion 34, e.g., implemented using a disk-shaped heat-insulating member made of a heat-resistant material such as graphite or SiC. The boat heat-insulating portion 34 is configured to prevent heat generated from the induction target 48 from being transferred to the lower side of the processing furnace 40.

A manifold 46 (used as a support member) is provided below the reaction tube 42 in a concentric relationship with the reaction tube 42. The manifold 46 is made of, e.g., stainless steel, and is formed in a cylindrical shape with open top and bottom ends so that the boat 30 can be loaded and unloaded through the manifold 46. The manifold 46 is installed to support the reaction tube 42 from below. An O-ring (not shown) (used as a seal member) is provided between the manifold 46 and the reaction tube 42. The manifold 46 is supported by a holder (not shown in the drawings), so that the reaction tube 42 is kept in a vertically-mounted state. As described above, an air-tight sealed reaction vessel is mainly made up of the combination of the reaction tube 42 and the manifold 46.

(Heater Unit)

The processing furnace 40 includes an induction target 48 to be heated by induction heating and an induction coil 50 (used as inductor) for generating magnetic fields to perform the induction heating. The induction target 48 may be made of, e.g., graphite, and is provided to surround the processing chamber 43. The induction target 48 is coupled to the manifold 46 by a connecting member, e.g., metal fittings (not shown in the drawings). In this manner, the lower end of the induction target 48 is supported by the manifold 46. In this configuration, a gap may be formed between a portion of the lower end of the induction target 48 and a portion of the upper end of the manifold 46. Further, the induction target 48 may not completely seal the processing chamber 43. In this case, a processing gas supplied into the processing chamber 43 may flow toward an internal heat-insulating member 54 (which will be described later). The induction coil 50 is provided outside the reaction tube 42 to surround the outer circumferential surface of the reaction tube 42. The induction coil 50 is supplied with an alternating current with a frequency range of, e.g., 10 kHz to 100 kHz and with a power of, e.g., 10 kW to 200 kW, from an alternating current source (not shown in the drawings). By supplying the alternating current to the induction coil 50, alternating magnetic fields are applied to the induction target 48. Thus, an induced current flows through the induction target 48 so that the induction target 48 can generate heat. As heat is generated by the induction target 48, the wafers 14 held in the boat 30 and the processing chamber 43 are heated to a temperature of, e.g., 1500° C. to 1800° C., by radiant energy emitted from the induction target 48.

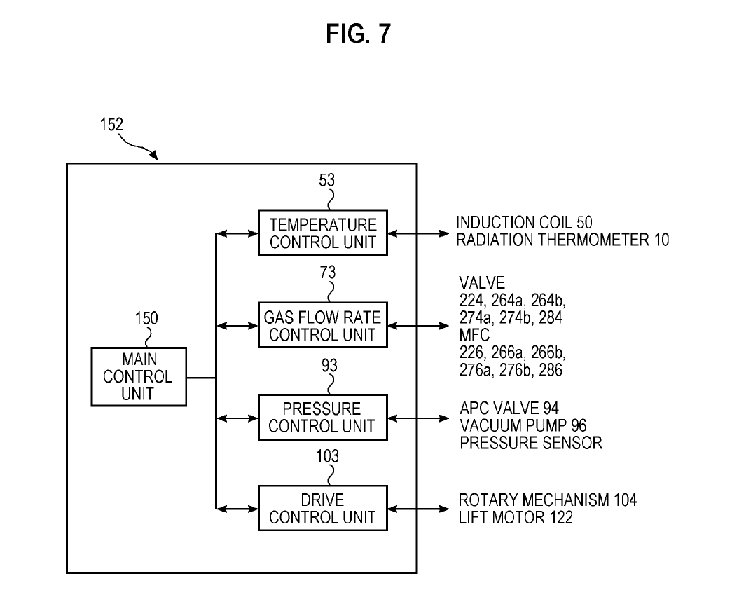

The temperature of the induction target 48 is detected by, e.g., a radiation thermometer 11 (used as a temperature detector) installed outside the induction coil 50. The induction coil 50 and the radiation thermometer 11 are electrically connected to a temperature control unit 53 provided in a controller 152 (used as a control unit, which will be described below) (see FIG. 7). The temperature control unit 53 controls the current supply to the induction coil 50 based on the temperature information detected by the radiation thermometer 11, thereby ensuring that the processing chamber 43 has a predetermined temperature distribution at a predetermined timing.

In between the induction target 48 and the reaction tube 42, there is provided an internal heat-insulating member 54 (used as a heat insulator) for restraining radiant energy, particularly infrared rays, emitted from the induction target 48 from being transferred outside. The internal heat-insulating member 54 is made of, e.g., felt-shaped carbons alone or felt-shaped carbons coated with a corrosion-resistant material such as tantalum carbide (TaC). The internal heat-insulating member 54 is coupled to the manifold 46 by a connecting member such as metal fittings (not shown in the drawings) so that the lower end of the internal heat-insulating member 54 can be supported by the manifold 46. The internal heat-insulating member 54 serves to restrain energy emitted from the induction target 48 from being transferred to the reaction tube 42 or outside of the reaction tube 42, thereby maintaining the inside of the processing chamber 43 at a specified temperature. An outer heat-insulating member 56, e.g., with a water-cooling type structure, is provided outside the induction coil 50 to surround the reaction tube 42. The outer heat-insulating member 56 is configured to restrain energy generated within the reaction tube 42 from being transferred outside. Further, outside the outer heat-insulating member 56, a magnetic field seal 58 is provided to prevent magnetic fields generated by the induction coil 50 from leaking to the outside. As shown in FIGS. 2 and 4, a first gap 44 is formed between the induction target 48 and the internal heat-insulating member 54, and a second gap 45 is formed between the internal heat-insulating member 54 and the reaction tube 42. In the present embodiment, the internal heat-insulating member 54 is held by a connecting member (not shown in the drawings) so that a gap can be formed between a portion of the lower end of the internal heat-insulating member 54 and a portion of the upper end of the manifold 46. In this configuration, an inert gas supplied to the second gap 45 may flow into the first gap 44 through the gap formed between the internal heat-insulating member 54 and the manifold 46, as will be described later.

A heater unit according to the present embodiment includes as a main feature the induction target 48, the induction coil 50, the alternating current source (not shown), the radiation thermometer 11 and the internal heat-insulating member 54.

(First Gas Supply Unit and Second Gas Supply Unit)

A plurality of gas supply nozzles is provided on the side wall of the manifold 46. More specifically, there are provided a Si (silicon) atom-containing gas supply nozzle 260 for supplying a Si (silicon) atom-containing gas as a source gas, a C (carbon) atom-containing gas supply nozzle 270 for supplying a C (carbon) atom-containing gas as a source gas, a dopant gas supply nozzle 280 for supplying a dopant gas and a plurality of inert gas supply nozzles 220a, 220b and 220c for supplying an inert gas as a purge gas. For example, a trichlorosilane (SiHCl₃) gas may be used as the Si atom-containing gas, and a propane (C₃H₈) gas may be used as the C atom-containing gas. A H (hydrogen) atom-containing gas (used as a carrier gas) may be mixed with the Si atom-containing gas and the C atom-containing gas. For example, a hydrogen (H₂) gas may be used as the H atom-containing gas. Further, for example, a nitrogen (N₂) gas used in forming an n-type doped layer may be used as the dopant gas, and a nitrogen (N₂) gas may be used as the inert gas.

In the present embodiment, a first gas generally refers to a processing gas used in processing the wafers 14 within the processing chamber 43, such as the Si atom-containing gas, the C atom-containing gas, the H atom-containing gas or the dopant gas. A second gas generally refers to the inert gas used in purging the first gap 44.

The Si atom-containing gas supply nozzle 260, the C atom-containing gas supply nozzle 270, the dopant gas supply nozzle 280 and the inert gas supply nozzles 220a, 220b and 220c are formed in an L-like shape using a heat-resistant material, e.g., carbon graphite. The Si atom-containing gas supply nozzle 260, the C atom-containing gas supply nozzle 270, the dopant gas supply nozzle 280 and the inert gas supply nozzles 220a, 220b and 220c are provided to horizontally pass through the side wall of the manifold 46 at their upstream portions.

The downstream portions of the Si atom-containing gas supply nozzle 260 and the C atom-containing gas supply nozzle 270 are arranged within the processing chamber 43. Specifically, the downstream portions of the Si atom-containing gas supply nozzle 260 and the C atom-containing gas supply nozzle 270 are arranged to run upwards along the inner wall of the induction target 48 and to extend near the upper end of the boat 30. Si atom-containing gas supply ports 268 and C atom-containing gas supply ports 278 for supplying the gases between the horizontally stacked wafers 14 are formed in the side portions of the Si atom-containing gas supply nozzle 260 and the C atom-containing gas supply nozzle 270.

The downstream portion of the dopant gas supply nozzle 280 is arranged within the processing chamber 43. Specifically, the downstream portion of the dopant gas supply nozzle 280 is arranged to run upwards along the base side surface of the boat 30 and to extend near the lower structure of the boat 30 within the processing chamber 43. A dopant gas supply port 288 is formed in the downstream portion of the dopant gas supply nozzle 280.

The downstream portions of the inert gas supply nozzles 220a, 220b and 220c are arranged in the second gap 45 formed between the reaction tube 42 and the internal heat-insulating member 54. Specifically, the downstream portions of the inert gas supply nozzles 220a, 220b and 220c are arranged to run upwards along the inner wall of the reaction tube 42 and to extend to a position higher than the upper end of the internal heat-insulating member 54. As shown in FIG. 4, the inert gas supply nozzles 220a, 220b and 220c are arranged in opposing relationship with second exhaust ports 230a, 230b and 230c (which will be described below) to interpose the internal heat-insulating member 54 therebetween. The inert gas supply nozzles 220a, 220b and 220c are equally spaced apart from each other in the inner circumferential direction of the reaction tube 42. In other words, the distance between the inert gas supply nozzles 220a and 220b is equal to the distance between the inert gas supply nozzles 220b and 220c. Inert gas supply ports 228a, 228b and 228c are formed at the downstream ends of the inert gas supply nozzles 220a, 220b and 220c in the positions higher than the upper end of the internal heat-insulating member 54.

The downstream end of a Si atom-containing gas supply pipe 262a is connected to the upstream end of the Si atom-containing gas supply nozzle 260. As shown in FIG. 3, a SiHCl₃ gas source 265a, a mass flow controller (MFC) 266a used as a flow rate controller (flow rate control means) and a valve 264a are sequentially provided in the Si atom-containing gas supply pipe 262a from the upstream side thereof. The downstream end of a H atom-containing gas supply pipe 262b is connected to the Si atom-containing gas supply pipe 262a at the downstream side of the valve 264a. A H₂ gas source 265b, a mass flow controller (MFC) 266b used as a flow rate controller (flow rate control means) and a valve 264b are sequentially provided in the H atom-containing gas supply pipe 262b from the upstream side thereof.

The downstream end of a C atom-containing gas supply pipe 272a is connected to the upstream end of the C atom-containing gas supply nozzle 270. As shown in FIG. 3, a C₃H₈ gas source 275a, a mass flow controller (MFC) 276a used as a flow rate controller (flow rate control means) and a valve 274a are sequentially provided in the C atom-containing gas supply pipe 272a from the upstream side thereof. The downstream end of a H atom-containing gas supply pipe 272b is connected to the C atom-containing gas supply pipe 272a at the downstream side of the valve 274a. A H₂ gas source 275b, a mass flow controller (MFC) 276b used as a flow rate controller (flow rate control means) and a valve 274b are sequentially provided in the H atom-containing gas supply pipe 272b from the upstream side thereof.

The downstream end of a dopant gas supply pipe 282 is connected to the upstream end of the dopant gas supply nozzle 280. As shown in FIG. 3, a N₂ gas source 285, a mass flow controller (MFC) 286 used as a flow rate controller (flow rate control means) and a valve 284 are sequentially provided in the dopant gas supply pipe 282 from the upstream side thereof.

The branched downstream ends of an inert gas supply pipe 222 are connected to the upstream ends of the inert gas supply nozzles 220a, 220b and 220c, respectively. As shown in FIG. 3, a N₂ gas source 225, a mass flow controller (MFC) 226 used as a flow rate controller (flow rate control means) and a valve 224 are sequentially provided in the inert gas supply pipe 222 from the upstream side thereof.

A gas flow rate control unit 73 of the controller 152 (which will be described later) is electrically connected to the valves 224, 264a, 264b, 274a, 274b and 284 and the MFCs 226, 266a, 266b, 276a, 276b and 286 (see FIG. 7). The gas flow rate control unit 73 is configured to control the valves 224, 264a, 264b, 274a, 274b and 284 and the MFCs 226, 266a, 266b, 276a, 276b and 286 so that the flow rate of the Si atom-containing gas, the C atom-containing gas, the H atom-containing gas and the dopant gas supplied to the processing chamber 43 and the flow rate of the inert gas supplied to the first gap 44 can be maintained at a predetermined flow rate at a predetermined timing.

A first gas supply unit according to the present embodiment is mainly made up of the Si atom-containing gas supply nozzle 260, the Si atom-containing gas supply ports 268, the Si atom-containing gas supply pipe 262a, the H atom-containing gas supply pipe 262b, the C atom-containing gas supply nozzle 270, the C atom-containing gas supply ports 278, the C atom-containing gas supply pipe 272a, the H atom-containing gas supply pipe 272b, the dopant gas supply nozzle 280, the dopant gas supply port 288, the dopant gas supply pipe 282, the valves 224, 264a, 264b, 274a, 274b and 284, the MFCs 226, 266a, 266b, 276a, 276b and 286, the SiHCl₃ gas source 265a, the H₂ gas source 265b, the C₃H₈ gas source 275a, the H₂ gas source 275b and the N₂ gas source 285.

Further, a second gas supply unit according to the present embodiment is mainly made up of the inert gas supply nozzles 220a, 220b and 220c, the inert gas supply ports 228a, 228b and 228c, the inert gas supply pipe 222, the valve 224, the MFC 226 and the N₂ gas source 225.

(Exhaust Unit)

An exhaust port 98 for discharging the atmospheric gas from the processing chamber 43 therethrough is provided on the side wall of the manifold opposite the inert gas supply nozzles 220a, 220b and 220c arranged within the second gap 45, with the processing chamber 43 interposed between the exhaust port 98 and the inert gas supply nozzles 220a, 220b and 220c. The upstream end of an exhaust pipe 92 is connected to the exhaust port 98. A pressure sensor (not shown), an APC (Auto Pressure Controller) valve 94 used as a pressure control device and a vacuum pump 96 are sequentially provided in the exhaust pipe 92 from the upstream side thereof. A pressure control unit 93 of the controller 152 (which will be set forth later) is electrically connected to the pressure sensor (not shown), the APC valve 94 and the vacuum pump 96 (see FIG. 7). The pressure control unit 93 is configured to control the opening of the APC valve 94 so that the pressure within the processing chamber 43 can be maintained at a predetermined pressure at a predetermined time. The processing gas supplied into the processing chamber 43 is discharged from the exhaust port 98 mostly through the opening 290 provided in the manifold 46.

Second exhaust ports 230a, 230b and 230c (used as communication holes) configured to connect the second gap 45 and the internal space of the manifold 46 to each other (in the same direction as the radial direction of the exhaust port 98 along the vertical center axis of the reaction tube 42) are provided in the upper end portion of the manifold 46, which is disposed in the space defined by the internal heat-insulating member 54 and the reaction tube 42. The inert gas supplied to the second gap 45 and the first gap 44 is discharged from the exhaust port 98 mostly through the second exhaust ports 230a, 230b and 230c. As shown in FIG. 4, the second exhaust ports 230a, 230b and 230c formed in a plurality of openings are arranged in an opposing relationship with the inert gas supply nozzles 220a, 220b and 220c, with the internal heat-insulating member 54 interposed between the second exhaust ports 230a, 230b and 230c and the inert gas supply nozzles 220a, 220b and 220c. The second exhaust ports 230a, 230b and 230c are arranged at regular intervals along the inner circumferential direction of the reaction tube 42. In other words, the distance between the second exhaust ports 230a and 230b is equal to the distance between the second exhaust ports 230b and 230c. The total cross-sectional area of the second exhaust ports 230a, 230b and 230c, i.e., the total aperture area obtained by adding up the aperture areas of the respective second exhaust ports 230a, 230b and 230c, is set to be smaller than the cross-sectional area of the opening 290 of the manifold 46 which is taken in a direction perpendicular to the vertical center axis of the reaction tube 42.

An exhaust unit according to the present embodiment is mainly made up of the second exhaust ports 230a, 230b and 230c, the exhaust port 98, the exhaust pipe 92, the pressure sensor (not shown), the APC valve 94 and the vacuum pump 96.

As described above, the inert gas supply nozzles 220a, 220b and 220c and the second exhaust ports 230a, 230b and 230c are provided at mutually opposing positions to interpose the internal heat-insulating member 54 therebetween. Further, the inert gas supply ports 228a, 228b and 228c of the inert gas supply nozzles 220a, 220b and 220c are positioned higher than the upper end of the internal heat-insulating member 54. As a result, the inert gas is supplied to a position in the second gap 45, which is farthest away from the second exhaust ports 230a, 230b and 230c. While being diffused in the second gap 45, the inert gas flows along a substantially long path until it is discharged from the second exhaust ports 230a, 230b and 230c to the exhaust port 98. This prolongs the time of the inert gas staying in the second gap 45.

Since the total cross-sectional area of the second exhaust ports 230a, 230b and 230c is set to be smaller than the cross-sectional area of the opening 290 of the manifold 46, the discharging speed of the inert gas is controlled more than that of the processing gas. The reduced gas conductance makes it possible to prolong the time of the inert gas staying in the second gap 45.

Inasmuch as the time of the inert gas staying in the second gap 45 is prolonged by the configuration described above, the inert gas can be spread over substantially all the areas of the second gap 45. This makes it possible to purge the second gap 45 with the inert gas. Moreover, the inert gas supplied to the second gap 45 can be diffused from the gap between the lower end of the internal heat-insulating member 54 supported by, e.g., metal fittings, and the upper end of the manifold 46 to the first gap 44 formed between the induction target 48 and the internal heat-insulating member 54. This makes it possible to restrain the processing gas supplied into the processing chamber 43 from entering the first gap 44 or the second gap 45.

Further, the pressure control unit 93 of the controller 152 may control the amount of the inert gas being supplied so that the pressure in the first gap 44 and the second gap 45 can be kept higher than the pressure within the processing chamber 43 in which the wafers 14 are being processed. This makes it possible to further restrain the processing gas supplied into the processing chamber 43 from entering the first gap 44 or the second gap 45. In particular, since the total cross-sectional area of the second exhaust ports 230a, 230b and 230c is set to be smaller than the cross-sectional area of the opening 290 of the manifold 46, it is possible to make the staying time of the inert gas greater than that of the processing gas. Further, the pressure control unit 93 of the controller 152 may easily control the pressure in the second gap 45 to be kept at a predetermined value, which also makes it possible to increase the pressure in the first gap 44 up to a certain level in proportion to the pressure in the second gap 45.

Inasmuch as the inert gas supplied to the first gap 44 and the second gap 45 is mostly discharged from the second exhaust ports 230a, 230b and 230c, even if particles are generated from, e.g., the internal heat-insulating member 54 and possibly exist in the first gap 44 or the second gap 45, such particles can be discharged together with the inert gas.

(Periphery Structure of Processing Furnace)

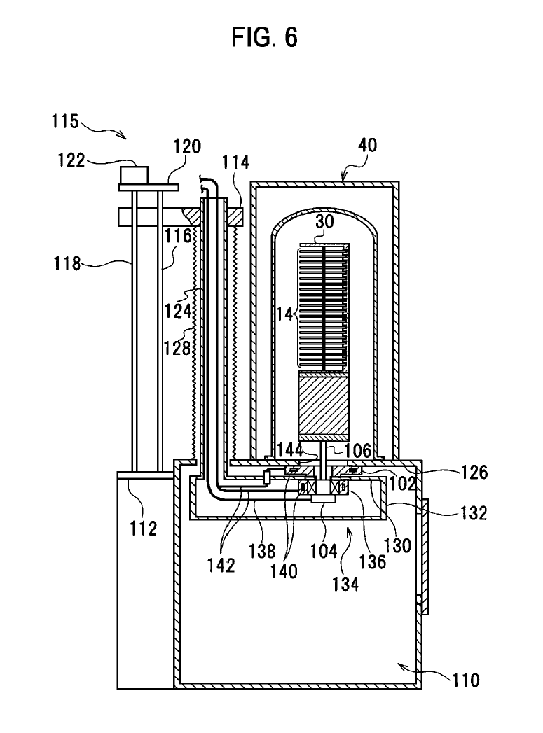

FIG. 6 is a schematic view showing the processing furnace 40 according to the first embodiment and the periphery structure thereof. As shown in FIG. 6, a load lock chamber 110 (used as a preparatory chamber) is provided below the processing furnace 40. A boat elevator 115 is provided on the outer surface of the side wall defining the load lock chamber 110. The boat elevator 115 includes a lower base plate 112, a guide shaft 116, a ball screw 118, an upper base plate 120, a lift motor 122, a lift plate 130 and a bellows 128. The lower base plate 112 is horizontally fixed to the outer surface of the side wall defining the load lock chamber 110. The guide shaft 116 fitted to a lift table 114 and the ball screw 118 threadedly coupled to the lift table 114 are attached to the lower base plate 112 in a vertical posture. The upper base plate 120 is fixed to the upper ends of the guide shaft 116 and the ball screw 118 in a horizontal posture. The ball screw 118 is rotated by the lift motor 122 provided in the upper base plate 120. The guide shaft 116 is configured to restrain horizontal rotation of the lift table 114 while allowing vertical movement thereof. The lift table 114 is moved up and down by rotating the ball screw 118.

A hollow lift shaft 124 is fixed to the lift table 114 in a vertical posture. The joint portion of the lift table 114 and the lift shaft 124 is kept air-tight. The lift shaft 124 is configured to vertically move together with the lift table 114. The lower end portion of the lift shaft 124 extends through a top plate 126 defining the load lock chamber 110. The inner diameter of a through-hole formed in the top plate 126 of the load lock chamber 110 is set to be greater than the outer diameter of the lift shaft 124 so that the lift shaft 124 and the top plate 126 should not make contact with each other. The bellows 128 as a hollow flexible body with flexibility is provided between the load lock chamber 110 and the lift table 114 in such a manner as to surround the periphery of the lift shaft 124. The joint portion of the lift table 114 and the bellows 128 and the joint portion of the top plate 126 and the bellows 128 are kept air-tight, thereby keeping the load lock chamber 110 in an air-tight state. The bellows 128 is flexible so that it may adapt itself to the vertical movement of the lift table 114. The inner diameter of the bellows 128 is set to be sufficiently greater than the outer diameter of the lift shaft 124 so that the lift shaft 124 and the bellows 128 should not make contact with each other.

The lift plate 130 is horizontally fixed to the lower end of the lift shaft 124 protruding into the load lock chamber 110. The joint portion of the lift shaft 124 and the lift plate 130 is kept air-tight. A seal cap 102 is air-tightly attached to the upper surface of the lift plate 130 through a seal member such as an O-ring. The seal cap 102 may be made of metal, e.g., stainless steel, and is formed in a disk-like shape. If the lift motor 122 is driven to rotate the ball screw 118 and to lift up the lift table 114, the lift shaft 124, the lift plate 130 and the seal cap 102, the boat 30 is loaded into the processing furnace 40 (in a boat loading operation) and the opening (furnace opening) 144 of the processing furnace 40 is closed by the seal cap 102 through an O-ring. On the other hand, if the lift motor 122 is driven to rotate the ball screw 118 and to lower down the lift table 114, the lift shaft 124, the lift plate 130 and the seal cap 102, the boat 30 is unloaded from the processing furnace 40 (in a boat unloading operation). A drive control unit 103 of a controller 152 (used as a control unit which will be described later) is electrically connected to the lift motor 122 (see FIG. 7). The drive control unit 103 controls the lift motor 122 so that the boat elevator 115 can perform a desired operation at a desired timing.

A drive unit cover 132 is air-tightly attached to the lower surface of the lift plate 130 through a seal member such as an O-ring. A drive unit storage case 134 is made up of the lift plate 130 and the drive unit cover 132. The internal space of the drive unit storage case 134 is isolated from the atmosphere within the load lock chamber 110. A rotary mechanism 104 is provided within the drive unit storage case 134. An electric power supply cable 138 is connected to the rotary mechanism 104. The electric power supply cable 138 extends from the upper end of the lift shaft 124 to the rotary mechanism 104 through the inside of the lift shaft 124 so that electric power can be supplied to the rotary mechanism 104. The upper end portion of a rotational shaft 106 of the rotary mechanism 104 extends through the seal cap 102 to support the boat 30 as a substrate holder from below. The wafers 14 held in the boat 30 can be rotated within the processing furnace 40 by operating the rotary mechanism 104. The drive control unit 103 is electrically connected to the rotary mechanism 104. The drive control unit 103 controls the rotary mechanism 104 to perform a desired operation at a desired timing.

A cooling mechanism 136 is provided around the rotary mechanism 104 within the drive unit storage case 134. Coolant flow paths 140 are formed in the cooling mechanism 136 and the seal cap 102. Coolant pipes 142 for supplying cooling water are connected to the coolant flow paths 140. The coolant pipes 142 extend from the upper end of the lift shaft 124 to the coolant flow paths 140 through the inside of the lift shaft 124 so that the cooling water can be supplied to the coolant flow paths 140.

(Controller)

FIG. 7 is a block diagram illustrating a configuration of controlling respective units of the substrate processing apparatus 10 according to the present embodiment. As shown in FIG. 7, the substrate processing apparatus 10 includes a controller 152 (used as a control unit) configured to control the operations of respective units of the substrate processing apparatus 10. The controller 152 includes a main control unit 150. Further, the controller 152 includes a temperature control unit 53, a gas flow rate control unit 73, a pressure control unit 93 and a drive control unit 103, which are electrically connected to the main control unit 150. The main control unit 150 includes an operation unit and an input unit (not shown in the drawings).

### (2) Substrate Processing Process

Next, description will be made on a method of epitaxially growing, e.g., SiC films on the wafers 14 (used as substrates) made of, e.g., Si or SiC, using the substrate processing apparatus 10 of the afore-mentioned configuration. This substrate processing process may be carried out as one step of a semiconductor device manufacturing process. In the following description, the operations of the respective units of the substrate processing apparatus 10 are controlled by the controller 152.

(Wafer Loading Step)

First, the pod 16 containing a plurality of wafers 14 is placed on the pod stage 18. The pod 16 is transferred from the pod stage 18 to the pod rack 22 by the pod conveying device 20. The pod 16 placed on the pod rack 22 is conveyed to the pod opener 24 by the pod conveying device 20. The lid of the pod 16 is opened by the pod opener 24. The number of the wafers 14 contained in the pod 16 is detected by the wafer number detector 26. Then, the wafers 14 are taken out of the pod 16 and transferred to the boat 30 by the wafer transfer machine 28.

After charging the wafers 14 into the boat 30 (in a wafer charging operation), the boat 30 holding the wafers 14 is loaded into the processing chamber 43 by the lifting operation of the lift table 114 and the lift shaft 124, which is driven by the lift motor 122 (in a boat loading operation). In this state, the seal cap 102 seals the lower end of the manifold 46 through an O-ring. When loading the boat 30 into the processing chamber 43, an inert gas may be supplied from an inert gas source (not shown) to the inside of the induction target 48, thereby preventing the internal space of the processing chamber 43 from being exposed to an oxygen atmosphere.

(Pressure Reducing Step and Temperature Elevating Step)

Subsequently, the supply of the inert gas into the processing chamber 43 is stopped and the processing chamber 43 is evacuated by the vacuum pump 96. The induction coil 50 is supplied with an alternating current with a frequency range of, e.g., 10 kHz to 100 kHz and with a power of, e.g., 10 kW to 200 kW, from an alternating current source (not shown in the drawings). As a result, alternating magnetic fields are applied to the induction target 48, thereby allowing an induced current to flow through the induction target 48 so that the induction target 48 can generate heat. Then, the wafers 14 held in the boat 30 and the inside of the processing chamber 43 are heated to a temperature of, e.g., 1500° C. to 1800° C., by energy (radiant heat) emitted from the induction target 48. At this time, the amount of current supplied to the induction coil 50 is feedback controlled based on the temperature information detected by the radiation thermometer 11, thereby ensuring that the processing chamber 43 has a predetermined temperature distribution. Subsequently, the boat 30 and the wafers 14 are rotated by the rotary mechanism 104.

(Inert Gas Supply Step)

Next, the valve 224 is opened and an inert gas (used as a second gas), more specifically an N₂ gas, the flow rate of which is controlled by the MFC 226, begins to be supplied to the second gap 45 from the inert gas supply ports 228a, 228b and 228c of the inert gas supply nozzles 220a, 220b and 220c. The N₂ gas supplied to the second gap 45 is diffused within the second gap 45. At the same time, a part of the N₂ gas is diffused into the first gap 44 through the gap formed between the internal heat-insulating member 54 and the manifold 46. The N₂ gas flows along a substantially long path extending from the inert gas supply ports 228a, 228b and 228c to the second exhaust ports 230a, 230b and 230c and is discharged from the exhaust port 98 leading to the vacuum pump 96. Since the total cross-sectional area of the second exhaust ports 230a, 230b and 230c is set to be smaller than the cross-sectional area of the opening 290 of the manifold 46, the discharging speed of the inert gas is controlled to be low.

This enables the N₂ gas to spread over substantially all the areas of the first gap 44, thereby purging the first gap 44. The amount of the N₂ gas supplied is controlled by the controller 152, whereby the pressure of the second gap 45 can be kept beforehand at a predetermined value, e.g., a value greater than the internal pressure of the processing chamber 43 when the wafers 14 are processed therein (which will be described later). The N₂ gas supplied to the second gap 45 is also indirectly supplied to the first gap 44. This makes it possible to increase the pressure in the first gap 44 up to a certain level. For example, the pressure in the first gap 44 can be kept beforehand at a level higher than the internal pressure of the processing chamber 43 when the wafers 14 are processed therein. At this time, the inert gas supplied to the first gap 44 and the second gap 45 is mostly discharged from the second exhaust ports 230a, 230b and 230c. Therefore, even if particles are generated from, e.g., the internal heat-insulating member 54 and possibly exist in the first gap 44, such particles can be discharged beforehand together with the N₂ gas.

The supply of the N₂ gas to the first gap 44 and the second gap 45 may continue until the processing of the wafers 14 is completed (which will be described later), i.e., while the processing gas is supplied into the processing chamber 43. This helps sustain the effect of maintaining the pressure in the first gap 44 and the second gap 45 and discharging the particles in the course of processing the wafers 14.

(Processing Gas Supply Step)

Subsequently, the valves 264a and 264b are opened and a mixed gas of a SiHCl₃ gas (used as the Si atom-containing gas) and a H₂ gas (used as the H atom-containing gas), the flow rates of which are controlled by the MFCs 266a and 266b, begins to be supplied into the processing chamber 43 from the Si atom-containing gas supply ports 268 of the Si atom-containing gas supply nozzle 260. At this time, the valves 274a and 274b are also opened and a mixed gas of a C₃H₈ gas (used as the C atom-containing gas) and a H₂ gas (used as the H atom-containing gas), the flow rates of which are controlled by the MFCs 276a and 276b, begins to be supplied into the processing chamber 43 from the C atom-containing gas supply ports 278 of the C atom-containing gas supply nozzle 270. At this time, the valve 284 is also opened and a N₂ gas (used as the dopant gas), the flow rate of which is controlled by the MFC 286, begins to be supplied into the processing chamber 43 from the dopant gas supply port 288 of the dopant gas supply nozzle 280. The SiH₄ gas, the C₃H₈ gas, the H₂ gas and the N₂ gas supplied into the processing chamber 43 (used as the first gas) flow parallel to the wafers 14 through the processing chamber 43, i.e., the inside of the induction target 48, and are discharged from the exhaust pipe 92. Thus, all the wafers 14 are efficiently and uniformly exposed to the processing gas and SiC films epitaxially grow on the surfaces of the wafers 14. At this time, the pressure in the processing chamber 43 is detected by the pressure sensor. The APC valve 94 connected to the vacuum pump 96 through the exhaust pipe 92 is feedback controlled based on the pressure measured by the pressure sensor, so that the internal space of the processing chamber 43 can be kept at a predetermined pressure (or vacuum degree).

At this time, the flow rate of the processing gas (used as the first gas) and the flow rate of the inert gas (used as the second gas) are controlled by the controller 152, so that the pressure within the reaction tube 42 is controlled differently in the processing chamber 43, the first gap 44 and the second gap 45. In particular, the pressure in the processing chamber 43 is controlled to be less than the pressure in the first gap 44, which is again controlled to be less than the pressure in the second gap 45. FIG. 5 is an explanatory view showing the pressure difference within the reaction tube 42 in the course of processing the wafers 14. As shown in FIG. 5, the internal pressure of the reaction tube 42 in the course of processing the wafers 14 is controlled so that the pressure P₄₅ in the second gap 45 becomes greatest while the pressure P₄₃ in the processing chamber 43 becoming smallest. As a result, the pressure P₄₄ in the first gap 44 is controlled to be smaller than the pressure P₄₅ in the second gap 45, but greater than the pressure P₄₃ in the processing chamber 43. For example, if the processing gas is supplied into the processing chamber 43 at a total flow rate of 150 slm and if the N₂ gas is supplied from the inert gas supply nozzles 220a, 220b and 220c at a flow rate of 5 slm when the pressure P₄₃ in the processing chamber 43 reaches 100 Torr, the pressure P₄₅ in the second gap 45 and the pressure P₄₄ in the first gap 44 can be kept at 110 Torr and 105 Torr, respectively. This makes it possible to restrain the processing gas supplied into the processing chamber 43 from entering the first gap 44 or the second gap 45.

By continuously supplying the inert gas to the second gap 45 and the first gap 44 in the course of processing the wafers 14 as described above, it is possible to restrain the processing gas supplied into the processing chamber 43 from entering the second gap 45 or the first gap 44. This makes it possible to restrain degradation of the internal heat-insulating member 54 which would otherwise be caused by, e.g., the contact of the internal heat-insulating member 54 with the processing gas such as the H₂ gas, and thus restraining generation of particles. Moreover, it is possible to restrain unnecessary product materials from adhering to, e.g., the inner wall of the reaction tube 42 or the outer wall of the internal heat-insulating member 54. If the product materials adhere to the inner wall of the reaction tube 42, the product materials may hinder the detection of a temperature of the induction target 48 by, e.g., the radiation thermometer 11 provided outside the induction coil 50. According to the present embodiment, it is possible to restrain product materials from adhering to the inner wall or other portions of the reaction tube 42 and to accurately detect the temperature of the induction target 48, which assists in enhancing the throughput of the substrate processing operation.

Certain processing conditions of the wafers 14 in the present embodiment are described below by way of example. SiC films epitaxially grow on the wafers 14 by constantly keeping the following processing conditions at predetermined values within the ranges of the respective processing conditions.
(a) Processing conditions within the processing chamber 43

Temperature: 1500° C. to 1800° C.

Pressure P₄₃: 10 Torr to 200 Torr (1333 Pa to 26666 Pa)

Amount of supplying the first gas

SiHCl₃ gas flow rate: 0.1 slm to 1.0 slm

C₃H₈ gas flow rate: 0.1 slm to 1.0 slm

H₂ gas flow rate (sum): 100 slm to 200 slm

N₂ gas flow rate: 0.001 slm to 0.01 slm
(b) Processing conditions within the first gap 44

Pressure P₄₄: 15 Torr to 205 Torr
(c) Processing conditions within the second gap 45

Pressure P₄₅: 20 Torr to 210 Torr

N₂ gas flow rate: 5 slm to 10 slm

(Temperature Reducing Step and Atmospheric Pressure Restoring Step)

If the SiC films of a desired thickness epitaxially grow after a predetermined time, the valves 264a, 264b, 274a, 274b and 284 are closed to stop supplying the SiH₄ gas, the C₃H₈ gas, the N₂ gas and the H₂ gas into the processing chamber 43. Further, the supply of the alternating current to the induction coil 50 is stopped to reduce the temperature of the induction target 48, the boat 30 and the wafers 14 until it reaches a predetermined temperature (e.g., about 600° C.). In the course of reducing the temperature, an inert gas is supplied to the inside of the induction target 48 from an inert gas source (not shown), thereby substituting the internal atmosphere of the induction target 48 with the inert gas and restoring the internal pressure of the processing chamber 43 to an atmospheric pressure. Thereafter, the valve 224 is closed to stop supplying the N₂ gas to the second gap 45 and the first gap 44. As such, by continuously supplying the inert gas to the second gap 45 and the first gap 44 while substituting the internal atmosphere of the processing chamber 43 with the inert gas, it is possible to restrain the processing gas within the processing chamber 43 from entering the first gap 44 or the second gap 45 and to restrain degradation of the internal heat-insulating member 54.

(Wafer Unloading Step)

Thereafter, the seal cap 102 is moved down by the lift motor 122 to open the furnace opening 144 of the processing furnace 40, and the boat 30 holding the processed wafers 14 is unloaded through the furnace opening 144 outside of the processing furnace 40 (in a boat unloading operation). Then, the boat 30 is allowed to wait at a predetermined position until all the wafers 14 held in the boat 30 are cooled down. If the wafers 14 in the waiting boat 30 are cooled to a predetermined temperature, the wafers 14 are taken out of the boat 30 by the wafer transfer machine 28 and are conveyed into the empty pod 16 positioned in the pod opener 24. Subsequently, the pod 16 containing the wafers 14 is conveyed to the pod rack 22 or the pod stage 18 by the pod conveying device 20. In this manner, the pod 16 holding the processed wafers 14 therein is unloaded outside of the housing 12.

### (3) Effects According to the Present Embodiment

The present embodiment provides one or more effects set forth below.

(a) The substrate processing apparatus 10 according to the present embodiment includes the first gas supply unit configured to supply the first gas such as the processing gas into the processing chamber 43 and the second gas supply unit configured to supply the second gas such as the inert gas to the first gap 44. The second gas supply unit is also configured to supply the inert gas to the second gap 45. This helps restrain the processing gas supplied into the processing chamber 43 from entering the first gap 44 or the second gap 45.

If the processing gas enters the first gap 44 and if the processing gas, particularly the H atom-containing gas such as the H₂ gas, makes contact with the internal heat-insulating member 54, there may occur, e.g., hydrogen infiltration (a phenomenon in which H₂ infiltrates a metallic material and the H₂ gas makes contact with the metallic material at a high temperature and high pressure and degrades the mechanical properties of the metallic material), which may degrade, e.g., the internal heat-insulating member 54 and generate particles. As mentioned above, the internal heat-insulating member 54 is made of fibrous materials, e.g., felt-like carbons, and the H₂ gas may easily infiltrate into the gaps within the fibrous materials. If the processing gas such as the H₂ gas is restrained from entering the first gap 44 as in the present embodiment, it is possible to restrain degradation of the internal heat-insulating member 54 and generation of the particles, thereby reducing adherence of the particles to, e.g., the wafers 14. This makes it possible to enhance the substrate processing throughput and to improve productivity. Degradation of the internal heat-insulating member 54 may be restrained to a certain degree by, e.g., coating an anti-corrosion material such as tantalum carbide (TaC) on the surfaces of the fibrous materials. However, if the contact of the H₂ gas with the internal heat-insulating member 54 is restrained in the manner as presented in the present embodiment, it is possible to more reliably restrain degradation of the internal heat-insulating member 54.

In addition, by restraining the processing gas from entering the first gap 44 or the second gap 45, it is possible to restrain unnecessary product materials from adhering to the inner wall of the reaction tube 42. This enables the radiation thermometer 11 provided outside the induction coil 50 to accurately detect the temperature of the induction target 48, thereby enhancing the substrate processing throughput and improving the productivity.

(b) According to the present embodiment, the manifold 46 (used as a support unit) configured to support the lower ends of the reaction tube 42, the induction target 48 and the internal heat-insulating member 54 (used as a heat insulator) includes the exhaust port 98 for evacuating the interior of the processing chamber 43. The exhaust port 98 is positioned in an opposing relationship with the inert gas supply nozzles 220a, 220b and 220c with the processing chamber 43 interposed between the exhaust port 98 and the inert gas supply nozzles 220a, 220b and 220c. Further, the inert gas supply nozzles 220a, 220b and 220c provided in the second gap 45 extend to the position higher than the upper end of the internal heat-insulating member 54, and the inert gas supply ports 228a, 228b and 228c are provided in the position higher than the upper end of the internal heat-insulating member 54. In addition, the manifold 46 includes the second exhaust ports 230a, 230b and 230c configured to connect the gap provided between the induction target 48 and the reaction tube 42 to the internal space of the manifold 46. The aperture area of the second exhaust ports 230a, 230b and 230c is set to be smaller than the cross-sectional area of the opening 290 of the manifold 46 taken in the direction perpendicular to the vertical center axis of the reaction tube 42. This makes it possible to prolong the time of the inert gas staying in the second gap 45.

Since the staying time of the inert gas is prolonged by the configuration described above, the inert gas can spread over substantially all the areas of the second gap 45 and the first gap 44, which facilitates increasing the pressure in the first gap 44 and the second gap 45. This makes it possible to more effectively restrain the processing gas from entering the first gap 44 and the second gap 45.

(c) According to the present embodiment, the substrate processing apparatus 10 includes the controller 152 (used as a control unit) configured to control at least the first gas supply unit and the second gas supply unit so that the pressure P₄₄ in the first gap 44 becomes greater than the pressure P₄₃ within the processing chamber 43. In addition, the controller 152 controls at least the first gas supply unit and the second gas supply unit so that the pressure P₄₅ in the second gap 45 becomes greater than the pressure P₄₃ within the processing chamber 43 and the pressure P₄₄ in the first gap 44. This makes it possible to more reliably control the internal pressure of the reaction tube 42 and to more effectively restrain the processing gas from entering the first gap 44 and the second gap 45.

(d) In the present embodiment, the inert gas supplied to the first gap 44 and the second gap 45 is mostly discharged from the second exhaust ports 230a, 230b and 230c. Thus, even if particles are generated from, e.g., the internal heat-insulating member 54 and possibly exist in the first gap 44, such particles can be discharged together with the inert gas.

(e) In the present embodiment, the substrate processing apparatus 10 includes the controller 152 configured to control at least the first gas supply unit and the second gas supply unit so that the processing gas can be supplied into the processing chamber 43 after the inert gas is supplied to the first gap 44. This makes it possible to increase the pressure in the first gap 44 and the second gap 45 to a predetermined pressure prior to supplying the processing gas into the processing chamber 43, thereby more effectively restraining the processing gas from entering the first gap 44 and the second gap 45.

(f) In the present embodiment, the substrate processing apparatus 10 includes the controller 152 of the configuration described above. In this configuration, the particles present in the first gap 44 and the second gap 45 can be discharged prior to processing the wafers 14, thereby more effectively restraining the particles from adhering to, e.g., the wafers 14.

### Second Embodiment

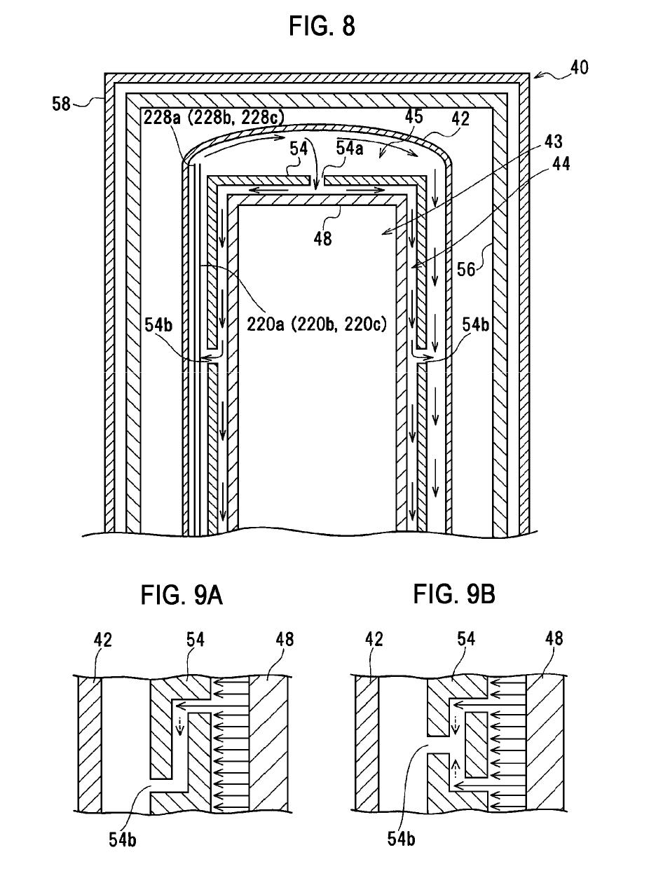

Next, a substrate processing apparatus according to a second embodiment will be described with reference to FIGS. 8 and 9. The substrate processing apparatus of the present embodiment differs from the substrate processing apparatus of the first embodiment in that a plurality of flow holes 54a and 54b is provided in the internal heat-insulating member 54. Other configurations of the present embodiment remain the same as those of the first embodiment. The elements having the same functions as those of the substrate processing apparatus 10 described above will be designated by like reference symbols and will not be described in detail.

FIG. 8 is a section view showing the flow holes 54a and 54b of the internal heat-insulating member 54 provided within the processing furnace 40 according to the present embodiment. As shown in FIG. 8, a flow hole 54a is provided on the upper end surface of the internal heat-insulating member 54. Only one flow hole 54a may be provided, e.g., at the center of the upper end surface of the internal heat-insulating member 54. Alternatively, a plurality of flow holes 54a may be evenly or unevenly distributed, e.g., throughout the entire upper end surface of the internal heat-insulating member 54. Flow holes 54b are provided on the side wall of the internal heat-insulating member 54. Only one flow hole 54b may be provided, e.g., at a certain point on the side surface of the internal heat-insulating member 54. Alternatively, a plurality of flow holes 54b may be evenly or unevenly distributed, e.g., throughout the entire side surface of the internal heat-insulating member 54. The internal heat-insulating member 54 may include a plurality of doughnut-shaped members separated in directions perpendicular to the vertical center axis of the reaction tube 42. The doughnut-shaped members may be connected to one another by joint members such as metal fittings to constitute the internal heat-insulating member 54. In this case, flow holes 54b may be provided by forming groove-like gaps running along the outer circumference of the internal heat-insulating member 54 in the connection portions between the doughnut-shaped members.

The inert gas supplied to the second gap 45 from the inert gas supply nozzles 220a, 220b and 220c can flow between the first gap 44 and the second gap 45 through the flow holes 54a and 54b. In FIG. 8, one example of the flowing state of the inert gas supplied to the second gap 45 is shown by arrows. A part of the inert gas supplied to the second gap 45 from the inert gas supply ports 228a, 228b and 228c enters the first gap 44, e.g., through the flow hole 54a provided on the upper end surface of the internal heat-insulating member 54. The inert gas entering the upper area of the first gap 44 flows down along the first gap 44 toward the exhaust port 98 provided in the lower portion of the reaction tube 42. A part of the inert gas flowing along the first gap 44 enters the second gap 45 again through the flow holes 54b provided on the side surface of the internal heat-insulating member 54. In this manner, the flow hole 54a and the flow holes 54b serve to introduce/discharge the inert gas to/from the first gap 44, respectively. This makes the inert gas entering the first gap 44 hard to stay within the first gap 44 and allows the inert gas to flow between the first gap 44 and the second gap 45. According to the present embodiment, since the inert gas supplied to the second gap 45 enters the first gap 44 through the flow holes 54a and 54b, the present embodiment is applicable when there is no gap between the manifold 46 and the internal heat-insulating member 54.

In some embodiments, the flow holes 54a and 54b may be provided with a labyrinth structure. FIG. 9A is a section view showing one example of a labyrinth structure applied to the flow holes 54b, and FIG. 9B is a section view showing another example of the labyrinth structure applied to the flow holes 54b. In the example shown in FIG. 9A, each of the flow holes 54b provided in the outer wall of the internal heat-insulating member 54 is curved in a crank shape and opened toward the induction target 48. In the example shown in FIG. 9B, each of the flow holes 54b provided in the outer wall of the internal heat-insulating member 54 is curved in a crank shape, bifurcated and opened toward the induction target 48. By employing the labyrinth structure, i.e., curved structured in forming the flow path of each of the flow holes 54b, it is possible to restrain radiant energy emitted from the induction target 48, particularly infrared rays, as indicated by arrows in FIGS. 9A and 9B, from leaking outside through the flow holes 54b. As a result, damage to the reaction tube 42 or other components, which would be caused by the energy, can be reduced

The present embodiment provides the same effects as the first embodiment.

(a) According to the present embodiment, the flow holes 54a and 54b configured to connect the first gap 44 and the second gap 45 to each other are provided in the internal heat-insulating member 54. Thus, the inert gas can be rapidly diffused to the first gap 44, so that the pressure in the first gap 44 is increased more rapidly than in the first embodiment described above. Moreover, it is possible to keep the pressure P₄₄ in the first gap 44 higher than in the first embodiment. This makes it possible to more reliably restrain the processing gas supplied to the processing chamber 43 from entering the first gap 44.

For example, if the processing gas is supplied into the processing chamber 43 under the same conditions as in the first embodiment so that the total amount of supplying the processing gas is equal to 150 slm, thereby maintaining the pressure P₄₃ within the processing chamber 43 at 100 Torr, and at this time, if the N₂ gas is supplied at a flow rate of 5 slm from the inert gas supply nozzles 220a, 220b and 220c, the pressure P₄₅ in the second gap 45 and the pressure P₄₄ in the first gap 44 can be maintained at 110 Torr and 105 Torr, respectively.

(b) Further, according to the present embodiment, the curved portion provided in the flow path of each of the flow holes 54a and 54b restrains the energy emitted from the induction target 48 from leaking to the second gap 45. This makes it possible to restrain the reaction tube 42 or other components from being damaged by the radiant energy emitted from the induction target 48.

(c) In addition, according to the present embodiment, the internal heat-insulating member 54 is made up of a plurality of doughnut-shaped members separated in directions perpendicular to the vertical center axis of the reaction tube 42. In this configuration, the joint portions of the separated doughnut-shaped members can be used as the flow holes 54b.

### Third Embodiment

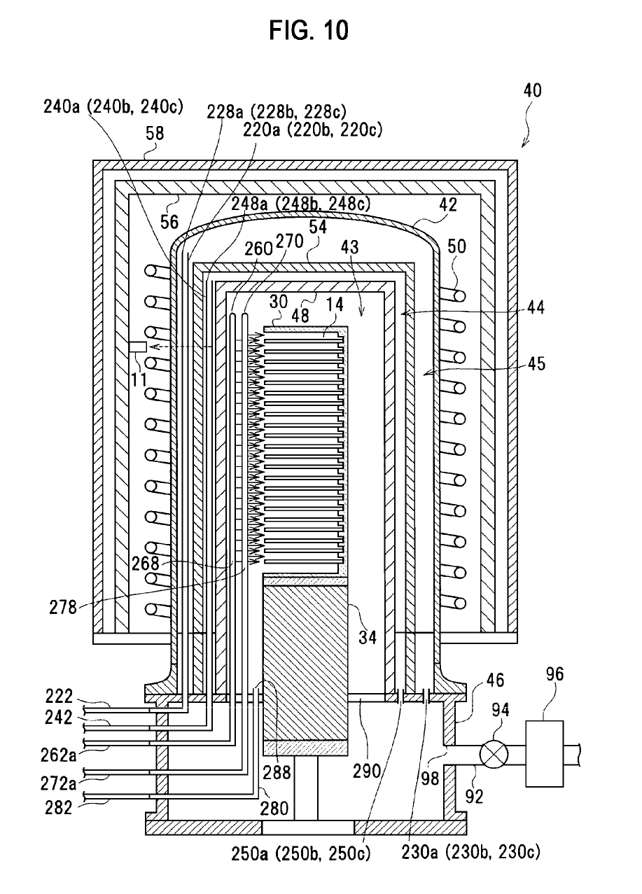

The following is a description of a substrate processing apparatus according to a third embodiment with reference to FIGS. 10 through 13. The substrate processing apparatus of the present embodiment differs from the substrate processing apparatus of the first embodiment in that inert gas supply nozzles are provided in the first gap 44 in addition to the inert gas supply nozzles 220a, 220b and 220c arranged in the second gap 45 and that a line for supplying the inert gas into the processing chamber 43 is additionally provided. Other configurations of the present embodiment remain the same as those of the first embodiment. The elements having the same functions as those of the substrate processing apparatus 10 described above will be designated by like reference symbols and will not be described in detail.

### (1) Configuration of Processing Furnace

FIG. 10 is a side section view showing a processing furnace 40 according to the present embodiment. As shown in FIG. 10, a plurality of inert gas supply nozzles 240a, 240b and 240c (used as second nozzles) configured to supply an inert gas (used as a purge gas) is provided in the first gap 44 between the induction target 48 and the internal heat-insulating member 54. Each of the inert gas supply nozzles 240a, 240b and 240c is made of, e.g., a heat-resistant material such as carbon graphite, and is formed in an L-like shape. The upstream portions of the inert gas supply nozzles 240a, 240b and 240c horizontally extend through the side wall of the manifold 46. The downstream portions of the inert gas supply nozzles 240a, 240b and 240c run upwards along the inner wall of the internal heat-insulating member 54 and extend to the position higher than the upper end of the induction target 48.

In the present embodiment, the inert gas supply nozzles 240a, 240b and 240c are provided to directly supply the inert gas to the first gap 44 as will be described later. Therefore, the present embodiment is applicable even when there is no gap formed between the manifold 46 and the internal heat-insulating member 54. FIG. 10 illustrates a case where no gap exists between the manifold 46 and the internal heat-insulating member 54.

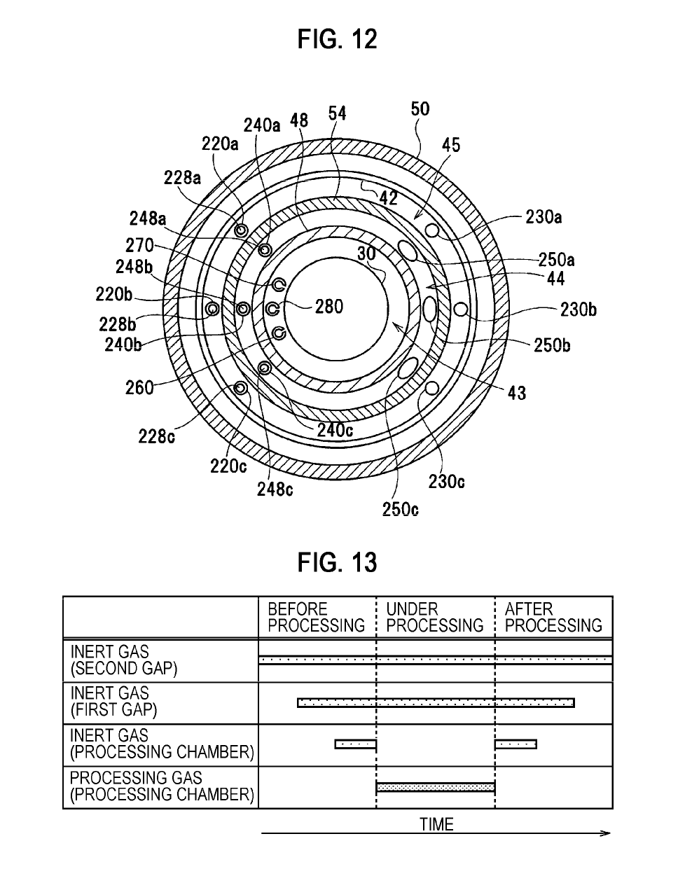

Referring to FIG. 12, the inert gas supply nozzles 240a, 240b and 240c are arranged opposite first exhaust ports 250a, 250b and 250c (which will be described later) with the induction target 48 interposed therebetween. The inert gas supply nozzles 240a, 240b and 240c are equally spaced apart in the inner circumferential direction of the internal heat-insulating member 54. In other words, the distance between the inert gas supply nozzles 240a and 240b is set to be equal to the distance between the inert gas supply nozzles 240b and 240c. Inert gas supply ports 248a, 248b and 248c are provided to be opened at the downstream ends of the inert gas supply nozzles 240a, 240b and 240c in the position higher than the upper end of the induction target 48.

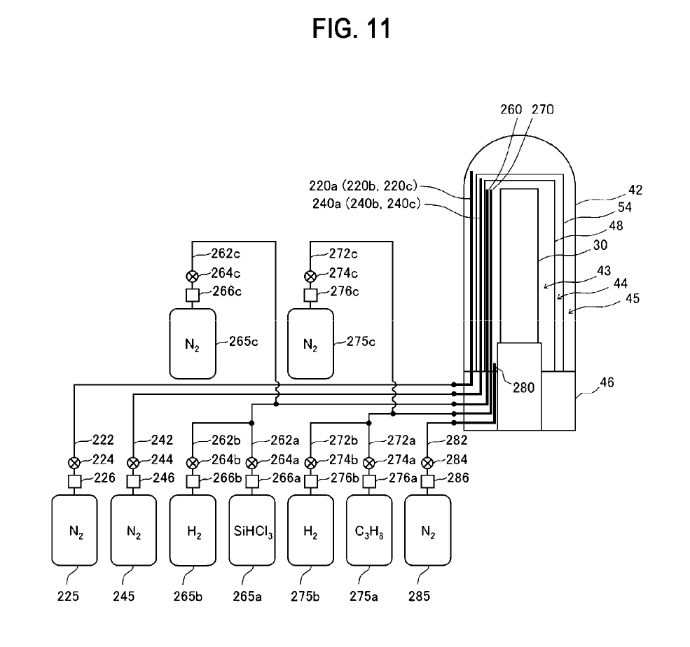

The branched downstream ends of an inert gas supply pipe 242 are connected to the upstream ends of the inert gas supply nozzles 240a, 240b and 240c, respectively. As shown in FIG. 11, a N₂ gas source 245, a mass flow controller (MFC) 246 used as a flow rate controller (flow rate control means) and a valve 244 are sequentially provided in the inert gas supply pipe 242 from the upstream side thereof.

The downstream end of an inert gas supply pipe 262c is connected to the upstream portion of a Si atom-containing gas supply pipe 262a which in turn is connected to the upstream end of a Si atom-containing gas supply nozzle 260. A N₂ gas source 265c, a mass flow controller (MFC) 266c used as a flow rate controller (flow rate control means) and a valve 264c are sequentially provided in the inert gas supply pipe 262c from the upstream side thereof.

The downstream end of an inert gas supply pipe 272c is connected to the upstream portion of a C atom-containing gas supply pipe 272a which in turn is connected to the upstream end of a C atom-containing gas supply nozzle 270. A N₂ gas source 275c, a mass flow controller (MFC) 276c used as a flow rate controller (flow rate control means) and a valve 274c are sequentially provided in the inert gas supply pipe 272c from the upstream side thereof.

The gas flow rate control unit 73 of the controller 152 shown in FIG. 7 is electrically connected to the valves 244, 264c and 274c and the MFCs 246, 266c and 276c. The gas flow rate control unit 73 is configured to control the valves 244, 264c and 274c and the MFCs 246, 266c and 276c so that the flow rate of the inert gas supplied to the first gap 44 and the processing chamber 43 can be maintained at a predetermined flow rate at a predetermined time.

A second gas supply unit according to the present embodiment is mainly made up of the inert gas supply nozzles 220a, 220b, 220c, 240a, 240b and 240c, the inert gas supply ports 228a, 228b, 228c, 248a, 248b and 248c, the inert gas supply pipes 222 and 242, the valve 224 and 244, the MFCs 226 and 246, and the N₂ gas sources 225 and 245, which includes the configuration as described above.

First exhaust ports 250a, 250b and 250c (used as communication holes) configured to connect the first gap 44 and the internal space of the manifold 46 to each other are provided in the upper end portion of the manifold 46 extending in the same direction as the radial direction of the exhaust port 98 along the vertical center axis of the reaction tube 42, which is disposed in the space defined by the internal heat-insulating member 54 and the induction target 48. The first exhaust ports 250a, 250b and 250c is made up of a plurality of openings and are arranged opposite the inert gas supply nozzles 240a, 240b and 240c with the induction target 48 interposed therebetween as shown in FIG. 12. The first exhaust ports 250a, 250b and 250c are equally spaced apart in the inner circumferential direction of the internal heat-insulating member 54. In other words, the distance between the first exhaust ports 250a and 250b is set to be equal to the distance between the first exhaust ports 250b and 250c. The total cross-sectional area of the first exhaust ports 250a, 250b and 250c, i.e., the total aperture area obtained by adding up the aperture areas of the respective first exhaust ports 250a, 250b and 250c, is set to be smaller than the cross-sectional area of the opening 290 of the manifold 46 taken in the direction perpendicular to the vertical center axis of the reaction tube 42. Moreover, the total aperture area of the first exhaust ports 250a, 250b and 250c is set to be greater than the total aperture area of the second exhaust ports 230a, 230b and 230c.

An exhaust unit according to the present embodiment is mainly made up of the second exhaust ports 230a, 230b and 230c, the first exhaust ports 250a, 250b and 250c, the exhaust port 98, the exhaust pipe 92, the pressure sensor (not shown), the APC valve 94 and the vacuum pump 96, which includes the configuration as described above.

As described above, the inert gas supply nozzles 240a, 240b and 240c and the first exhaust ports 250a, 250b and 250c are provided opposite each other with the induction target 48 interposed therebetween. Further, the inert gas supply ports 248a, 248b and 248c of the inert gas supply nozzles 240a, 240b and 240c are provided in the position higher than the upper end of the induction target 48. In this configuration, the inert gas is discharged along a substantially long path. The gas conductance can be controlled to be a small value by adjusting the total aperture area of the first exhaust ports 250a, 250b and 250c. Thus, the discharging speed of the inert gas can be controlled to be lower than the discharging speed of the processing gas. This prolongs the time of the inert gas staying in the first gap 44, which allows the inert gas to spread over substantially all the areas of the first gap 44, and thus purge the first gap 44 with the inert gas. Further, the pressure in the first gap 44 can be readily kept at a predetermined value by controlling the amount of supplying the inert gas. Since the inert gas supplied to the first gap 44 is mostly discharged from the first exhaust ports 250a, 250b and 250c, particles possibly existing in the first gap 44 can be discharged together with the inert gas.

In addition, the total aperture area of the first exhaust ports 250a, 250b and 250c of the first gap 44 is set to be smaller than the cross-sectional area of the opening 290 of the manifold 46, but greater than the total aperture area of the second exhaust ports 230a, 230b and 230c of the second gap 45. This facilitates keeping, e.g., the pressure P₄₄ in the first gap 44 higher than the pressure P₄₃ within the processing chamber 43 but lower than the pressure P₄₅ in the second gap 45. At this time, the N₂ gas is supplied to the first gap 44 by a separate gas supply system including the inert gas supply nozzles 240a, 240b and 240c, the inert gas supply ports 248a, 248b and 248c, the inert gas supply pipe 242, the valve 244, the MFC 246 and the N₂ gas source 245. This makes it possible to more precisely control the pressure P₄₄ in the first gap 44. In the present embodiment, the pressure P₄₄ in the first gap 44 can be kept higher than the pressure P₄₅ in the second gap 45 by controlling the flow rate of the N₂ gas supplied from the inert gas supply nozzles 220a, 220b and 220c and the inert gas supply nozzles 240a, 240b and 240c to the first gap 44 and the second gap 45, respectively.

### (2) Substrate Processing Process

Next, a description will be made of a process to epitaxially grow SiC films on the wafers 14 using the substrate processing apparatus according to the present embodiment.

FIG. 13 is a gas supply timing chart in the substrate processing process according to the present embodiment. The gas supply timing shown in FIG. 13 is controlled by the afore-mentioned controller 152. Initially, the wafers 14 are loaded into the processing chamber 43 and subjected to a pressure reducing step and a temperature elevating step. Thereafter, as shown in FIG. 13, the valve 224 is controlled to be opened and an inert gas (used as a second gas), more specifically an N₂ gas, the flow rate of which is controlled by the MFC 226, begins to be supplied to the second gap 45 from the inert gas supply ports 228a, 228b and 228c of the inert gas supply nozzles 220a, 220b and 220c. Then, the valve 244 is controlled to be opened and an inert gas (used as a second gas), more specifically an N₂ gas, the flow rate of which is controlled by the MFC 246, begins to be supplied to the first gap 44 from the inert gas supply ports 248a, 248b and 248c of the inert gas supply nozzles 240a, 240b and 240c.

Next, the valve 264c is controlled to be opened and a N₂ gas (used as an inert gas), the flow rate of which is controlled by the MFC 266c, is supplied into the processing chamber 43 from the Si atom-containing gas supply ports 268 of the Si atom-containing gas supply nozzle 260. In addition, the valve 274c is controlled to be opened and a N₂ gas (used as an inert gas), the flow rate of which is controlled by the MFC 276c, is supplied into the processing chamber 43 from the C atom-containing gas supply ports 278 of the C atom-containing gas supply nozzle 270.

Through the operations described above, prior to the processing of the wafers 14, the pressure in the second gap 45 and the first gap 44 can be controlled at a predetermined value, e.g., at a pressure greater than the internal pressure of the processing chamber 43 when processing the wafers 14. This restrains the processing gas from entering the first gap 44 or the second gap 45. Even if particles are generated from the internal heat-insulating member 54 or other components and exist in the first gap 44 or the second gap 45, such particles can be discharged together with the inert gas supplied to the first gap 44 or the second gap 45 prior to the processing of the wafers 14. This restrains the particles from adhering to, e.g., the wafers 14.

Further, by supplying the inert gas into the processing chamber 43, even if some particles exist in the processing chamber 43, such particles can be discharged prior to the processing of the wafers 14. This restrains the particles from adhering to the wafers 14, e.g., in the course of processing the wafers 14.

Next, the valves 264c and 274c are controlled to be closed to thereby stop supplying the N₂ gas into the processing chamber 43. The internal space of the processing chamber 43 is evacuated and depressurized by the vacuum pump 96. Then, as in the first embodiment described above, a processing gas (used as a second gas) is supplied into the processing chamber 43 so that SiC films can epitaxially grow on the wafers 14. At this time, as in the first embodiment described above, the pressure within the reaction tube 42 in the course of processing the wafers 14 is controlled so that the pressure P₄₃ in the processing chamber 43 becomes greater than the pressure P₄₄ in the first gap 44, which again becomes greater than the pressure P₄₅ in the second gap 45. At this time, the total aperture area of the first exhaust ports 250a, 250b and 250c of the first gap 44 is set to be smaller than the cross-sectional area of the opening 290 of the manifold 46 but greater than the total aperture area of the second exhaust ports 230a, 230b and 230c of the second gap 45. Accordingly, this facilitates keeping, e.g., the pressure P₄₄ in the first gap 44 higher than the pressure P₄₃ within the processing chamber 43 but lower than the pressure P₄₅ in the second gap 45. Further, since the N₂ gas is supplied to the first gap 44 by a separate gas supply system, it is possible to more precisely control the pressure P₄₄ in the first gap 44. For example, if the processing gas is supplied into the processing chamber 43 under the same conditions as the first embodiment so that the total amount of supplying the processing gas reaches 150 slm and the pressure P₄₃ within the processing chamber 43 is kept at 100 Torr, and at this time, if the N₂ gas is supplied at a flow rate of 2.5 slm from the inert gas supply nozzles 220a, 220b and 220c and at a flow rate of 2.5 slm from the inert gas supply nozzles 240a, 240b and 240c, the pressure P₄₅ in the second gap 45 and the pressure P₄₄ in the first gap 44 can be maintained at 110 Torr and 105 Torr, respectively. This makes it possible to more reliably restrain the processing gas supplied into the processing chamber 43 from entering the first gap 44.

If the SiC films of a desired thickness epitaxially grow after a predetermined time, the supply of the processing gas into the processing chamber 43 is stopped. Thereafter, the valve 264c is controlled to be opened and the N₂ gas (used as the inert gas), the flow rate of which is controlled by the MFC 266c, is supplied into the processing chamber 43 from the Si atom-containing gas supply ports 268 of the Si atom-containing gas supply nozzle 260. In addition, the valve 274c is controlled to be opened and the N₂ gas (used as the inert gas), the flow rate of which is controlled by the MFC 276c, is supplied into the processing chamber 43 from the C atom-containing gas supply ports 278 of the C atom-containing gas supply nozzle 270. After a predetermined time lapses, the valves 264c and 274c are controlled to be closed to thereby stop supplying the N₂ gas into the processing chamber 43. Thereafter, the valve 244 is closed to stop supplying the N₂ gas to the first gap 44. Subsequently, the valve 224 is controlled to be closed to thereby stop supplying the N₂ gas to the second gap 45.

Through the operations described above, after completing the processing of the wafers 14, the processing gas remaining within the processing chamber 43 can be substituted with the processing gas. Further, by stopping the supply of the inert gas to the first gap 44 and the second gap 45, which is sequentially controlled in the order closer to the processing chamber 43, the processing gas is restrained from entering the first gap 44 or the second gap 45.

### (3) Effects According to the Present Embodiment

The present embodiment may provide the same effects as the first embodiment.

Further, according to the present embodiment, the second gas supply unit further includes the inert gas supply nozzles 240a, 240b and 240c for supplying the second gas to the first gap 44 between the induction target 48 and the internal heat-insulating member 54. This makes it possible to more reliably control the pressure P₄₄ in the first gap 44 and to restrain the processing gas from entering the first gap 44.

### Other Embodiments

While three inert gas supply nozzles 220a, 220b and 220c and three inert gas supply nozzles 240a, 240b and 240c are used in the foregoing embodiments, the number of the inert gas supply nozzles is not limited thereto but may be less than or greater than three. It may also be possible to use only one inert gas supply nozzle. Instead of separately arranging a plurality of inert gas supply nozzles as set forth above, it may be possible to employ an inert gas supply nozzle in which a single upstream end is branched into a plurality of nozzle portions at its downstream portion arranged in the first gap 44 or the second gap 45.

While the inert gas supply nozzles 220a, 220b and 220c and the inert gas supply nozzles 240a, 240b and 240c are respectively provided with the inert gas supply pipes 222 and 242, the valves 224 and 244, the MFCs 226 and 246, the N₂ gas sources 225 and 245, they may share a single set of the inert gas supply pipes, the valve, the MFC and the N₂ gas source with each other.

Further, while the Si atom-containing gas supply nozzle 260 and the C atom-containing gas supply nozzle 270 are respectively provided with the inert gas supply pipes 262c and 272c, the valves 264c and 274c, the MFCs 266c and 276c, the N₂ gas sources 265c and 275c, they may share a single set of the inert gas supply pipes, the valve, the MFC and the N₂ gas source with each other.

While three first exhaust ports 250a, 250b and 250c and three second exhaust ports 230a, 230b and 230c are employed in the foregoing embodiments, the number of the first exhaust ports or the second exhaust ports is not limited thereto but may be less than or greater than three. It may also be possible to use only one first exhaust port or second exhaust port.

Further, while the first exhaust ports 250a, 250b and 250c and the second exhaust ports 230a, 230b and 230c are provided to connect the first gap 44 and the second gap 45 to the internal space of the manifold 46, the first gap 44 and the second gap 45 may be in communication with the area below the substrate placing area in which the wafers 14 under processing is placed. In this configuration, the inert gas supplied to the first gap 44 and the second gap 45 may be discharged together with the processing gas from the exhaust port 98 through the area below the substrate placing area. This can be realized by forming communication holes in a portion of the induction target 48 or the internal heat-insulating member 54. In this case, as compared with the first and second embodiments, a path may be created through which the processing gas can easily infiltrate toward the internal heat-insulating member 54. However, the entry of the processing gas into the first gap 44 and the second gap 45 can be prevented by allowing the gas to flow from the second gap 45 and the first gap 44 toward the processing chamber 43, e.g., by keeping the pressure in the second gap 45 and the first gap 44 greater than the internal pressure of the processing chamber 43.

In this regard, the area of the processing chamber 43 below the substrate placing area in which the wafers 14 under processing is placed may function as an exhaust area through which the processing gas is discharged. Likewise, the internal space of the manifold 46 may also function as an exhaust area through which the processing gas is discharged. Accordingly, according to the present disclosure, the first exhaust ports 250a, 250b and 250c and the second exhaust ports 230a, 230b and 230c may be configured to bring the first gap 44 and the second gap 45 into communication with the exhaust area so that the processing gas and the inert gas can be discharged through the exhaust area.

In the foregoing embodiments, the inert gas is supplied to the first gap 44 or the second gap 45 prior to supplying the processing gas into the processing chamber 43, and the supply of the inert gas is stopped after stopping the supply of the processing gas into the processing chamber 43. However, in some embodiments, the inert gas may be supplied at least during the time when the processing gas is supplied into the processing chamber 43. Therefore, the timing of supplying the inert gas may be synchronized with the timing of supplying and cutting-off the processing gas into the processing chamber 43.

In the foregoing embodiments, the supply of the inert gas to the second gap 45 precedes the supply of the inert gas to the first gap 44. However, the supply of the inert gas may be performed in the reverse order. It may also be possible to simultaneously supply the inert gas to the first gap 44 and the second gap 45. Also, the timing of stopping the supply of the inert gas to the first gap 44 and the second gap 45 may be sequential or may be reversed. It may also be possible to simultaneously stop the supply of the inert gas to the second gap 45 and the first gap 44.

In the foregoing embodiments, the inert gas, more specifically the N₂ gas, is supplied as the purge gas. However, the gases usable as the purge gas are not limited thereto. For example, rare gases such as helium (He) gas, neon (Ne) gas, argon (Ar) gas, krypton (Kr) gas and xenon (Xe) gas or other chemically inert gases can be used as the purge gas. In addition to the inert gas, it is possible to use a processing gas such as ammonia (NH₃) gas or an etching gas such as hydrogen chloride (HCl) gas. When using a processing gas as the purge gas, the inner wall of the reaction tube 42 may be subjected to coating prior to processing the wafers 14, thereby avoiding damage to the reaction tube 42 and thus reducing generation of particles. When using an etching gas as the purge gas, product materials adhering to the reaction tube 42 may be etched away prior to processing the wafers 14.

In the foregoing embodiments, the SiHCl₃ gas is used as the Si atom-containing gas. Alternatively, silicon chloride or silicon hydrogen chloride such as tetrachlorosilane (SiCl₄) or dichlorosilane (SiH₂Cl₂) may be used as the Si atom-containing gas. In addition, silicon hydrogen chloride such as monosilane (SiH₄), disilane (Si₂H₆) or trisilane (Si₃H₃) and a halogen-based gas such as HCl or Cl₂ may be used in combination as the Si atom-containing gas.

In the foregoing embodiments, the C₃H₈ gas is used as the C atom-containing gas. Alternatively, ethylene (C₂H₄) or acetylene (C₂H₂) may be used as the C atom-containing gas.

In the foregoing embodiments, the H atom-containing gas, more specifically the H₂ gas, is used as the carrier gas. In addition to the H atom-containing gas, it is possible to use N₂ gas or a rare gas such as He gas, Ne gas, Ar gas, Kr gas or Xe gas as the carrier gas. In this case, the H atom-containing gas used as a reducing gas is added to the carrier gas.

In the foregoing embodiments, the N₂ gas forming an n-type doped layer is supplied as the dopant gas. However, if a p-type doped layer is to be formed, trimethylaluminum (TMA), diborane (B₂H₆) or boron trichloride (BCl₃) may be used as the dopant gas.

In the foregoing embodiments, the internal heat-insulating member 54 is made of, e.g., fibrous materials mainly composed of felt-like carbons. However, the material and shape of the internal heat-insulating member 54 is not limited thereto. If there is no need to significantly increase the temperature within the processing chamber 43, e.g., quartz (SiO2) other materials may be used as the internal heat-insulating member 54.

In the foregoing embodiments, the substrate processing apparatus 10 is a vertical heat treatment apparatus. However, the present invention is not limited thereto but may be applied to other types of substrate processing apparatuses provided with a processing chamber for processing wafers or other types of substrates in a depressurized state, e.g., a horizontal heat treatment apparatus or a sheet-fed heat treatment apparatus.

### Additional Embodiments of Present Disclosure

Hereinafter, some aspects of the present disclosure will be additionally described.

A first aspect of the present disclosure may provide a substrate processing apparatus, including a reaction tube; a processing chamber provided inside the reaction tube configured to process a substrate therein; an induction target provided inside the reaction tube to surround the processing chamber and configured to heat the substrate; a heat insulator provided inside the reaction tube to surround the induction target; an inductor provided outside the reaction tube and configured to inductively heat at least the induction target; a first gas supply unit configured to supply a first gas into the processing chamber; and a second gas supply unit configured to supply a second gas into a first gap formed between the induction target and the heat insulator.

According to a second aspect of the present disclosure, in the apparatus according to the first aspect, the first gas is a processing gas for processing the substrate.

According to a third aspect of the present disclosure, in the apparatus according to the first aspect, the second gas is an inert gas for purging at least the first gap.

According to a fourth aspect of the present disclosure, in the apparatus according to the first aspect, the second gas supply unit is further configured to supply the second gas to a second gap formed between the reaction tube and the heat insulator.

According to a fifth aspect of the present disclosure, in the apparatus according to the first aspect, the second gas supply unit includes at least a gas nozzle arranged in the second gap and provided with a gas supply port, the second gas supply unit being configured to supply the second gas through the gas supply port.

According to a sixth aspect of the present disclosure, in the apparatus according to the fifth aspect, the gas nozzle is configured to extend to a position higher than an upper end of the heat insulator, and the gas supply port is provided at a position higher than the upper end of the heat insulator.

According to a seventh aspect of the present disclosure, in the apparatus according to the fifth aspect, the gas nozzle includes a plurality of gas nozzles equally spaced apart from each other in an inner circumferential direction of the reaction tube.

According to an eighth aspect of the present disclosure, the apparatus according to the first aspect further includes a support unit configured to support the reaction tube, the induction target and the heat insulator, the support unit having an exhaust port configured to evacuate the processing chamber therethrough; and a communication hole configured to connect the first gap to an exhaust area to discharge the first gas therethrough, the second gas being allowed to flow to the exhaust area through the communication hole.

According to a ninth aspect of the present disclosure, in the apparatus according to the eighth aspect, the communication hole is provided on an upper surface of the support unit between the induction target and the reaction tube to connect the first gap to an internal space of the support unit.

According to a tenth aspect of the present disclosure, the apparatus according to the first aspect further includes a control unit configured to control at least the first gas supply unit and the second gas supply unit in such a manner that the pressure in the first gap becomes greater than the pressure within the processing chamber.

According to an eleventh aspect of the present disclosure, the apparatus according to the fourth aspect further includes a control unit configured to control at least the first gas supply unit and the second gas supply unit in such a manner that the pressure in the second gap becomes greater than the pressure within the processing chamber and the pressure in the first gap.

According to a twelfth aspect of the present disclosure, in the apparatus according to the fourth aspect, the heat insulator includes a flow hole configured to connect the first gap and the second gap to each other.

According to a thirteenth aspect of the present disclosure, in the apparatus according to the twelfth aspect, the flow hole includes a flow path defined by a curved portion for restraining the energy emitted from the induction target from leaking to the second gap.

According to a fourteenth aspect of the present disclosure, in the apparatus according to the first aspect, the heat insulator is made of fibrous materials.

According to a fifteenth aspect of the present disclosure, in the apparatus according to the first aspect, the heat insulator is made of carbon materials or carbon-containing materials, and the first gas supply unit is configured to supply at least a hydrogen gas or hydrogen-containing gas as the first gas.

According to a sixteenth aspect of the present disclosure, in the apparatus according to the first aspect, the heat insulator is made of felt-shaped carbons coated with a corrosion-resistant material.

According to a seventeenth aspect of the present disclosure, in the apparatus according to the sixteenth aspect, the heat insulator includes a plurality of members separated in directions perpendicular to a vertical center axis of the reaction tube.

According to an eighteenth aspect of the present disclosure, in the apparatus according to the third aspect, the second gas is a nitrogen gas or rare gas.

According to a nineteenth aspect of the present disclosure, in the apparatus according to the first aspect, the second gas supply unit further includes a second gas nozzle configured to supply the second gas to a first gap formed between the induction target and the heat insulator.

A twentieth aspect of the present disclosure may provide a semiconductor device manufacturing method, including: maintaining an atmosphere inside a processing chamber at a predetermined temperature by inductively heating an induction target by an inductor, the induction target being provided inside a reaction tube to surround the processing chamber, the inductor being provided outside the reaction tube, with a heat insulator provided inside the reaction tube to surround the induction target and configured to insulate energy generated from the induction target from reaction tube; and processing a substrate arranged within the processing chamber by supplying a first gas from a first gas supply unit into the processing chamber and supplying a second gas from a second gas supply unit to a first gap formed between the induction target and the heat insulator.

A twenty-first aspect of the present disclosure may provide a substrate manufacturing method, including: maintaining an atmosphere inside a processing chamber at a predetermined temperature by inductively heating an induction target by an inductor, the induction target being provided inside a reaction tube to surround the processing chamber, the inductor being provided outside the reaction tube, with a heat insulator provided inside the reaction tube to surround the induction target and configured to insulate energy generated from the induction target from reaction tube; and processing a substrate arranged within the processing chamber by supplying a first gas from a first gas supply unit into the processing chamber and supplying a second gas from a second gas supply unit to a first gap formed between the induction target and the heat insulator.

A twenty-second aspect of the present disclosure may provide a substrate manufacturing method, including: maintaining an atmosphere inside a processing chamber at a predetermined temperature by inductively heating an induction target by an inductor, the induction target being provided inside a reaction tube to surround the processing chamber, the inductor being provided outside the reaction tube, with a heat insulator provided inside the reaction tube to surround the induction target and configured to insulate energy generated from the induction target from reaction tube; and processing a substrate arranged within the processing chamber by supplying a first gas from a first gas supply unit into the processing chamber and supplying a second gas from a second gas supply unit to a first gap formed between the induction target and the heat insulator.

According to a twenty-third aspect of the present disclosure, the apparatus according to the fifth aspect further includes a support unit for supporting lower ends of the reaction tube, the induction target and the heat insulator, the support unit including an exhaust port for evacuation of the processing chamber, the exhaust port being arranged in an opposing relationship with the gas nozzle with the processing chamber interposed between the exhaust port and the gas nozzle, the gas nozzle extending to a position higher than an upper end of the heat insulator, the gas supply port being provided in a position higher than the upper end of the heat insulator.

According to a twenty-fourth aspect of the present disclosure, the apparatus according to the first aspect further includes a support unit configured to support the reaction tube, the induction target and the heat insulator, the support unit having an exhaust port configured to evacuate the processing chamber therethrough; and a communication hole configured to connect the first gap to an exhaust area to discharge the first gas therethrough, the second gas being allowed to flow to the exhaust area through the communication hole, the communication hole having an aperture area smaller than a cross-sectional area of an opening of the support unit which is taken in a direction perpendicular to a vertical center axis of the reaction tube, the opening of the support unit serving as a route through which the first gas is discharged to the exhaust port.

According to a twenty-fifth aspect of the present disclosure, in the apparatus according to the first aspect, the second gas supply unit includes a second gas nozzle arranged in the first gap and provided with a second gas supply port, the second gas supply unit being configured to supply the second gas through the second gas supply port.

According to a twenty-sixth aspect of the present disclosure, the apparatus according to the first aspect further includes a control unit configured to control at least the first gas supply unit and the second gas supply unit in such a manner that the first gas is supplied into the processing chamber after the second gas is supplied to the first gap.

According to the substrate processing apparatus, the semiconductor device manufacturing method, and the substrate manufacturing method of the above embodiments, it is possible to enhance the substrate processing throughput and to improve productivity.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a reaction tube;
a processing chamber provided inside the reaction tube configured to process a substrate therein;
an induction target provided inside the reaction tube to surround the processing chamber and configured to heat the substrate;
a heat insulator provided inside the reaction tube to surround the induction target;
an inductor provided outside the reaction tube and configured to inductively heat at least the induction target;
a first gas supply unit configured to supply a first gas into the processing chamber; and
a second gas supply unit configured to supply a second gas into a first gap formed between the induction target and the heat insulator.

2. The apparatus of claim 1, wherein the first gas is a processing gas for processing the substrate.

3. The apparatus of claim 1, wherein the second gas is an inert gas for purging at least the first gap.

4. The apparatus of claim 1, wherein the second gas supply unit is further configured to supply the second gas to a second gap formed between the reaction tube and the heat insulator.

5. The apparatus of claim 1, wherein the second gas supply unit includes at least a gas nozzle arranged in the second gap and provided with a gas supply port, the second gas supply unit being configured to supply the second gas through the gas supply port.

6. The apparatus of claim 5, wherein the gas nozzle is configured to extend to a position higher than an upper end of the heat insulator, and the gas supply port is provided at a position higher than the upper end of the heat insulator.

7. The apparatus of claim 5, wherein the gas nozzle includes a plurality of gas nozzles equally spaced apart from each other in an inner circumferential direction of the reaction tube.

8. The apparatus of claim 1, further comprising:
a support unit configured to support the reaction tube, the induction target and the heat insulator, the support unit having an exhaust port configured to evacuate the processing chamber therethrough; and
a communication hole configured to connect the first gap to an exhaust area to discharge the first gas therethrough, the second gas being allowed to flow to the exhaust area through the communication hole.

9. The apparatus of claim 8, wherein the communication hole is provided on an upper surface of the support unit between the induction target and the reaction tube to connect the first gap to an internal space of the support unit.

10. The apparatus of claim 1, further comprising:
a control unit configured to control at least the first gas supply unit and the second gas supply unit in such a manner that the pressure in the first gap becomes greater than the pressure within the processing chamber.

11. The apparatus of claim 4, further comprising:
a control unit configured to control at least the first gas supply unit and the second gas supply unit in such a manner that the pressure in the second gap becomes greater than the pressure within the processing chamber and the pressure in the first gap.

12. The apparatus of claim 4, wherein the heat insulator includes a flow hole configured to connect the first gap and the second gap to each other.

13. The apparatus of claim 12, wherein the flow hole includes a flow path defined by a curved portion for restraining the energy emitted from the induction target from leaking to the second gap.

14. The apparatus of claim 5, further comprising:
a support unit for supporting lower ends of the reaction tube, the induction target and the heat insulator, the support unit including an exhaust port for evacuation of the processing chamber, the exhaust port being arranged in an opposing relationship with the gas nozzle with the processing chamber interposed between the exhaust port and the gas nozzle, the gas nozzle extending to a position higher than an upper end of the heat insulator, the gas supply port being provided in a position higher than the upper end of the heat insulator.

15. The apparatus of claim 1, further comprising:
a support unit configured to support the reaction tube, the induction target and the heat insulator, the support unit having an exhaust port configured to evacuate the processing chamber therethrough; and
a communication hole configured to connect the first gap to an exhaust area to discharge the first gas therethrough, the second gas being allowed to flow to the exhaust area through the communication hole, the communication hole having an aperture area smaller than a cross-sectional area of an opening of the support unit which is taken in a direction perpendicular to a vertical center axis of the reaction tube, the opening of the support unit serving as a route through which the first gas is discharged to the exhaust port.

16. The apparatus of claim 1, wherein the second gas supply unit includes a second gas nozzle arranged in the first gap and provided with a second gas supply port, the second gas supply unit being configured to supply the second gas through the second gas supply port.

17. The apparatus of claim 1, further comprising:
a control unit configured to control at least the first gas supply unit and the second gas supply unit in such a manner that the first gas is supplied into the processing chamber after the second gas is supplied to the first gap.

18. The apparatus of claim 1, wherein the heat insulator includes a plurality of members separated in directions perpendicular to a vertical center axis of the reaction tube.

19. A semiconductor device manufacturing method, comprising:
inductively heating an induction target with an inductor, the induction target being provided inside a reaction tube and surrounding a processing chamber, the inductor being provided outside the reaction tube;
insulating energy generated from the induction target from the reaction tube with a heat insulator surrounding the induction target;
supplying a first gas from a first gas supply unit into the processing chamber; and
supplying a second gas from a second gas supply unit to a first gap formed between the induction target and the heat insulator.

20. A substrate manufacturing method, comprising:
maintaining an atmosphere inside a processing chamber at a predetermined temperature by inductively heating an induction target with an inductor, the induction target being provided inside a reaction tube to surround the processing chamber, the inductor being provided outside the reaction tube, with a heat insulator provided inside the reaction tube to surround the induction target and configured to insulate energy generated from the induction target from reaction tube; and
processing a substrate arranged within the processing chamber by supplying a first gas from a first gas supply unit into the processing chamber and supplying a second gas from a second gas supply unit to a first gap formed between the induction target and the heat insulator.
